(19) United States
(12) Patent Application Publication
(10) Pub. No.: US 2025/0311315 A1
(43) Pub. Date: Oct. 2, 2025

(54) SEMICONDUCTOR DEVICES WITH GUARD RING STRUCTURES

(71) Applicant: TEXAS INSTRUMENTS INCORPORATED, Dallas, TX (US)

(72) Inventors: Masahiko Higashi, Aizuwakamatsu-shi (JP); Dong Seup Lee, McKinney, TX (US); Jungwoo Joh, Allen, TX (US); Hiroshi Yamasaki, Aizuwakamatsu-shi (JP); Takayuki Enda, Aizuwakamatsu-shi (JP)

(21) Appl. No.: 18/621,708

(22) Filed: Mar. 29, 2024

(51) Int. Cl. H01L 29/06; H01L 21/768; H01L 23/522; H01L 29/20; H01L 29/778

(52) U.S. Cl. CPC H10D 62/102; H01L 21/76819; H01L 21/76883; H01L 23/5226; H10D 62/8503; H10D 30/47

(57) ABSTRACT

Semiconductor devices with guard ring structures are described. In some examples, a semiconductor device includes a semiconductor substrate, a III-N layer over the semiconductor substrate. The III-N layer extends past a device region of the semiconductor substrate. The semiconductor device further includes a guard ring surrounding the device region. The guard ring includes a discontinuity formed through the III-N layer and extending into the semiconductor substrate.

### FIELD OF THE DISCLOSURE

Disclosed implementations relate generally to the field of semiconductor devices and their fabrication. More particularly, but not exclusively, the disclosed implementations relate to III-N semiconductor devices including guard ring structures.

### BACKGROUND

Group III nitride materials (also referred to as III-N materials) possess a unique combination of physical and electrical properties found to be beneficial in modern microelectronics and optoelectronics. Among these properties are wide bandgap, high saturated drift rate, high breakdown voltage, high thermal conductivity, robust chemical and thermal stability, etc. Due to these characteristics, III-N materials are being considered as promising materials for fabrication of powerful high-frequency transistor structures capable of functioning at high temperatures and in hostile environments. Although the fabrication of devices including III-N materials with high yields remains a desirable goal for the semiconductor manufacturing industry, it is not without challenges as will be set forth below.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

Examples of the present disclosure are directed to semiconductor devices including III-N materials (or III-N semiconductor devices) having guard ring structures and methods of fabricating the same, where the guard ring structures are configured to provide protection against crack propagation during singulation. In one example, a semiconductor device is disclosed, which comprises, a semiconductor substrate, a III-N layer over the semiconductor substrate, where the III-N layer extends past a device region of the semiconductor substrate, and a guard ring surrounding the device region, the guard ring including a discontinuity formed through the III-N layer and extending into the semiconductor substrate. The III-N layer may extend past the guard ring to a scribe lane region surrounding the guard ring.

In one example, a method of fabricating a semiconductor device is disclosed. The method may comprise, among others, forming a III-N layer over a semiconductor substrate that includes a device region, a guard ring region, and a scribe lane region; and forming a guard ring in the guard ring region, where the guard ring surrounds the device region and includes a discontinuity formed through the III-N layer, the discontinuity extending into the semiconductor substrate. In one arrangement, the discontinuity may be formed before forming a transistor in the device region. In one arrangement, the discontinuity may be formed after forming a transistor in the device region.

In one example, a semiconductor structure is disclosed, which comprises, a semiconductor substrate, a III-N layer over the semiconductor substrate, where the III-N layer extends into a device region of the semiconductor substrate and into a scribe lane region of the semiconductor substrate, and a discontinuity surrounding the device region, the discontinuity formed through the III-N layer and extending into the semiconductor substrate. In one arrangement, the discontinuity may comprise a trench having a metal liner and filled with one or more dielectric materials. In some examples, the metal liner may be formed of a first metal layer of a metal interconnect system. In one arrangement, the discontinuity may comprise a trench devoid of a metal liner but filled with one or more dielectric materials.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described.

The accompanying drawings are incorporated into and form a part of the specification to illustrate one or more example implementations of the present disclosure. Various advantages and features of the disclosure are described in the following Detailed Description taken in connection with the appended claims and with reference to the attached drawing Figures in which:

FIG. 1A depicts a portion of a semiconductor wafer including a plurality of IC dies separated by a scribe lane grid, each IC die including a guard ring (GR) structure surrounding a device region according to some examples of the present disclosure;

FIG. 1B depicts a cross-sectional view of a device region of a representative semiconductor device, e.g., an IC die illustrated in FIG. 1A;

FIG. 2 depicts a cross-sectional view of a portion of the semiconductor wafer of FIG. 1A including an unsingulated IC die with a GR structure surrounding the device region and configured to arrest crack propagation in accordance with some examples of the present disclosure;

FIG. 3 is a flowchart of a method of fabricating a semiconductor device including a GR structure according to some examples;

FIG. 4 is a flowchart of a method of fabricating a semiconductor device including a GR structure with a discontinuity formed after a transistor formation according to some examples;

FIG. 5 is a flowchart illustrative of additional details relating to a method of fabricating a semiconductor device including a GR structure formed after a transistor formation according to some examples;

FIG. 6 is a flowchart illustrative of additional details relating to a method of fabricating a semiconductor device including a GR structure formed after a transistor formation according to some examples;

FIGS. 7A and 7B depict flowcharts relating to a method of fabricating a semiconductor device including a discontinuity in a III-N layer of a GR structure formed before a transistor formation according to some examples;

FIGS. 8A-80 depict cross-sectional views of a GR structure of an IC device at various stages of a process flow, where a discontinuity in a III-N layer of the GR structure may be formed before a transistor formation according to some examples of the present disclosure;

FIGS. 9A-9J depict cross-sectional views of a GR structure of an IC device at various stages of a process flow, where a discontinuity of the GR structure comprising a trench may be formed after a transistor formation according to some examples of the present disclosure;

FIGS. 10A-10K depict cross-sectional views of a GR structure of an IC device at various stages of a process flow, where a discontinuity of the GR structure comprising a trench may be formed after a transistor formation according to some examples of the present disclosure;

FIGS. 11A-11K depict cross-sectional views of a GR structure of an IC device at various stages of a process flow, where a discontinuity of the GR structure comprising a trench may be formed after a transistor formation according to some examples of the present disclosure;

FIG. 12 depicts a top plan view of a semiconductor device including a GR structure according to some examples of the present disclosure; and

FIGS. 13A and 13B depict cross-sectional views of semiconductor IC devices with additional examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of the present disclosure will be set forth below in the context of scribe seal structures, also referred to as guard ring structures, configured to arrest or otherwise mitigate crack propagation in semiconductor wafers during singulation.

The terms “scribelane” and “scribe lane” may include terms of similar import such as “scribe street”, “scribe line”, or simply “scribe”, etc., and refer to areas on a semiconductor wafer between adjacent integrated circuit (IC) dies (also referred to as “chips”, “dies”, “device dies”, “ICs” or “IC chips”, “semiconductor devices”, or terms of similar import) that are set aside for facilitating physical separation of the IC dies (i.e., singulation) in a dicing operation.

In semiconductor manufacturing, wafer dicing plays an important role in the quality of the product, e.g., singulated IC chips, before packaging. Some mechanical methods for dicing wafers (e.g., blade or saw dicing) pulverize the wafer material in the cutting path (known as “dicing street”, “kerf” or “kerf lane”, or terms of similar import) disposed in the scribe lane of the semiconductor wafer. In doing so, singulation techniques can cause cracks that may propagate from the cutting path to the IC dies—e.g., through the substrate material as well as any overlying semiconductor, dielectric, and/or conductive layers. As a result, the singulated IC chips may be damaged, and overall yields may be negatively impacted. Laser dicing may offer several advantages over mechanical dicing operations, especially for IC chips having small form factors (e.g., less than around 1.0 mm²), as it enables significant cost savings by facilitating a reduction both in the total scribe lane widths as well as kerf widths. However, laser dicing may still cause damage (e.g., cracks) that need to be contained from penetrating into the singulated IC chips.

The foregoing concerns continue to be relevant in the manufacture of semiconductor devices based on Group III nitride materials (i.e., III-N materials, III-N semiconductor materials) that are being investigated to replace silicon as a semiconductor material in a variety of applications including power electronics, among others. For example, gallium nitride (GaN) devices have gained considerable attention in recent years due to their exceptional electrical properties, such as high breakdown voltage, high electron mobility, and excellent thermal conductivity, thus making GaN devices highly desirable for applications such as power switches. Some semiconductor devices including III-N materials (e.g., III-N devices, IC chips including III-N devices) may be fabricated on silicon substrates, where the use of silicon as a substrate can offer several advantages, including its low cost, widespread availability, and compatibility with standard semiconductor processing techniques, thus increasing the manufacturability of III-N devices by leveraging well-established infrastructures for device fabrication and integration.

With respect to singulating IC chips including III-N devices, one or more III-N layers may be removed from the entire scribe lane so as to avoid crack propagation through the III-N layers during the singulation process. In some examples, the scribe lane's III-N material may be removed near the end of the overall process flow—e.g., before depositing a protective dielectric layer over the wafer. Because of the thicknesses of the III-N layers as well as various dielectric layers overlying the III—N layers, etching processes for removing the III-N layers can become challenging, especially where an increasing number of metallization levels are being contemplated (e.g., metallization levels exceed three (3) or more). Whereas certain etching processes may help reduce the overall thickness of overlying material in a scribe lane area, there may still be process reliability issues due to, e.g., residual photoresist debris caused in the attendant photolithography processes, as well as the potential for creating cracks or fissures at the dielectric sidewalls formed on each side of the scribe lane that could cause failures at subsequent testing such as biased high temperature accelerated stress testing (BHAST).

Various disclosed methods and structures of the present disclosure may be beneficially applied in IC manufacturing where a variety of guard ring (GR) structures surrounding the device area of a semiconductor die may be provided for reducing the potential for crack generation and/or propagation during singulation—e.g., utilizing laser or mechanical dicing. Further, examples set forth herein may be implemented without removing the III-N layers and/or dielectric layers, for instance, partially or completely, from the entire scribe lane areas, e.g., avoiding the risk of harmful debris generation. In other words, the III-N layers may be present in the scribe lane areas outside the GR structures. Whereas described examples may be expected to provide increased separation yields, no particular result is a requirement unless explicitly recited in a particular claim.

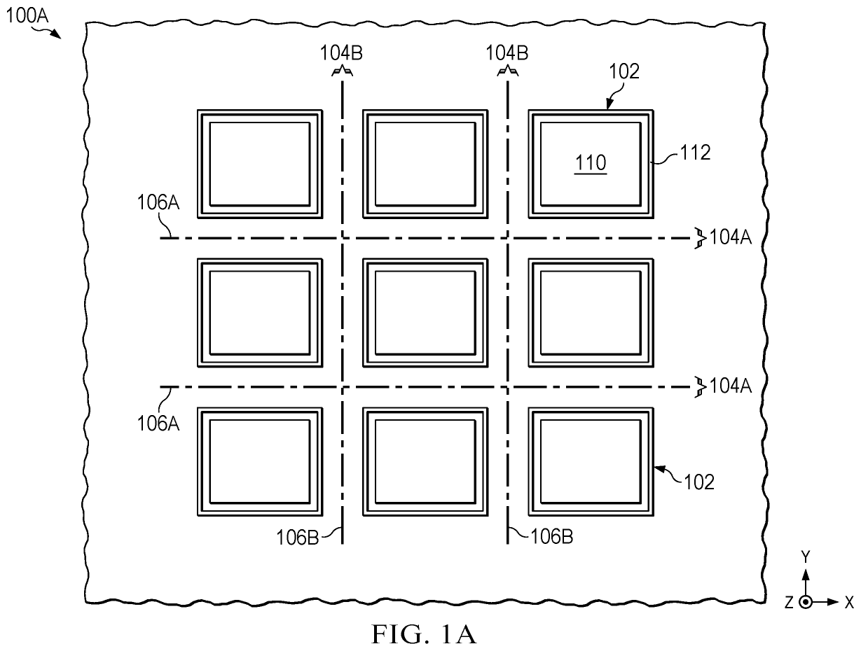

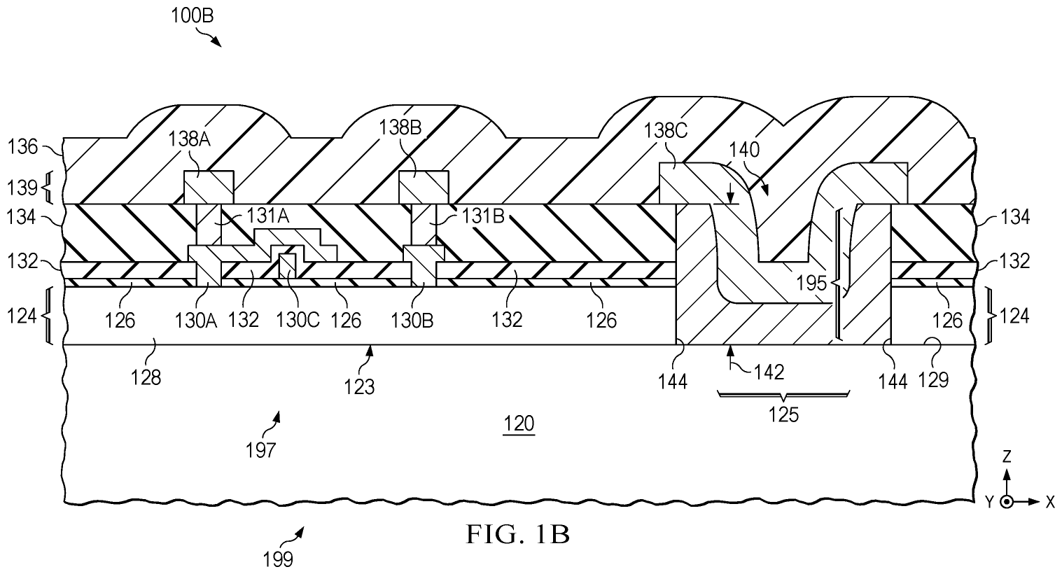

Referring to the drawings, FIG. 1A depicts a top plan view of a semiconductor wafer portion 100A including a plurality of IC dies separated by a scribe lane grid, each IC die including a guard ring (GR) structure surrounding a device region according to some examples of the present disclosure. For purposes of the present disclosure, an example IC die 102 may comprise any semiconductor device, including a III-N device, formed in or over a semiconductor substrate (not specifically shown). The IC dies 102 may be organized in an array and surrounded by horizontal scribe lanes 104A (e.g., along the X-axis) and vertical scribe lanes 104B (e.g., along the Y-axis) that are orthogonal to the horizontal scribe lanes 104A. The scribe lanes 104A, 104B form a scribe lane grid structure that includes one or more material layers or sublayers formed during the fabrication of the IC dies 102. In some examples, scribe lanes 104A, 104B may have a same width. In some examples, scribe lanes 104A, 104B may each have a different width. Depending on implementation and the dicing technologies involved, the scribe lane widths may vary from a few tens of microns (e.g., for laser dicing operations) to a few hundreds of microns or more (e.g., for mechanical dicing operations) in order to accommodate respective cutting lanes 106A, 106B.

According to examples herein, each semiconductor device or IC die 102 may comprise a device region 110, which may also be referred to as an active die region, surrounded by a GR structure 112. The GR structure 112 may comprise one or more guard rings or scribe seals configured to arrest crack propagation during singulation. As will be set forth in further detail below, each guard ring may include a discontinuity formed in a guard ring region (or GR region) of the semiconductor device 102. The GR region includes a material stack (e.g., comprising one or more III-N layers and/or dielectric layers) that extends past the device region 110 and into the corresponding scribe lanes 104A, 104B along X- and Y-directions. In the representative examples herein, the discontinuity may include a trench, with or without a metal liner, that may extend through the material stack and into the substrate material of the semiconductor device 102. For purposes of the present disclosure, the device region 110 may be a portion of the semiconductor substrate of the semiconductor device 102 in which one or more microelectronic components such as transistors, resistors, diodes, capacitors, etc., are fabricated, e.g., as discrete components and/or as an IC. Whereas the GR structure 112 may completely surround the device region 110 in some implementations, it is not a necessary requirement. For example, a GR structure 112 may include one or more segmented portions disposed on each side of the device region 110 depending on implementation.

FIG. 1B depicts a cross-sectional view of a device region 100B of a representative semiconductor device 199 that may be provided with a GR structure according to some examples. In some arrangements, device region 100B may be illustrative of the device region 110 shown in FIG. 1A, where the semiconductor device 199 is representative of a portion of the semiconductor die 102. The semiconductor device 199 includes a semiconductor substrate 120, which may be provided as part of a silicon wafer, for example, that may comprise p-type or n-type semiconductor material. Depending on integration and implementation, the semiconductor substrate 120 may represent a portion of the bulk wafer or a region (e.g., a well and/or buried layer and/or epitaxial layer).

A III-N layer stack 124 comprising a plurality of layers and/or sublayers may be formed over the substrate 120, which may be processed to form one or more electronic components such as transistors, diodes, etc., as part of the circuitry of the device region 100B. By way of illustration, a GaN field effect transistor (FET) 197 may be formed in an area 123, where the III-N layer stack 124 may comprise multiple layers/sublayers of suitable materials and compositions (e.g., GaN, AlGaN) as well as variable thicknesses depending on the technology and device application. In one example arrangement, a first GaN layer 128 may be disposed over an upper surface 129 of the substrate 120, where the GaN layer 128 may be formed to contain several sublayers. In some examples, the GaN layer 128 may include at least in part a nucleation layer, a buffer layer, as well as a graded region above the nucleation layer (not specifically shown), where the graded region may also contain aluminum in a range of concentrations. In some arrangements, the GaN layer 128 may also include a low defect region, not specifically shown, sometimes referred to as an unintentionally doped (UID) region, above the graded region, having essentially gallium nitride, optionally with some unintentional dopants.

Another layer in the III-N layer stack 124 may comprise a barrier layer 126 (e.g., including an aluminum gallium nitride (AlGaN)) formed over the GaN layer 128. Further, a channel sublayer may form in the GaN layer 128 as a result of forming the barrier layer 126, not specifically shown. The channel sublayer includes a two-dimensional electronic gas (2DEG) proximate to the interface between the GaN layer 128 and the barrier layer 126, located between a source terminal 130A and a drain terminal 130B. Moreover, a gate terminal 130C may be disposed between the source and drain terminals 130A, 130B and formed over the barrier layer 126. In some arrangements, other types of GaN layers, e.g., p-doped GaN or p-GaN, etc., may also be formed as part of the III-N layer stack 124. Whereas in a normally ON mode GaN FET device (i.e., a depletion mode device), the 2DEG channel extends from the source terminal region to the drain terminal region of the device without any discontinuity, in an enhancement mode device (i.e., a normally OFF mode device), the channel is absent in a gate region associated with the gate terminal until the device is turned on.

Depending on implementation, various constituent layers of the layer stack 124 may be formed by a sequence of vapor phase epitaxial processes, which may use a nitrogen-containing gas reagent/source such as ammonia, an aluminum-containing gas reagent/source such as trimethyl aluminum, and a gallium-containing gas reagent/source such as trimethyl gallium. In some arrangements, the GaN layer 128 may have a thickness in a range from 1.2 μm to 3.5 μm, depending in part on the maximum operating potential of the GaN FET. In some arrangements, the barrier layer 126 may have a thickness in a range from 5 nm to 30 nm. For purposes of the present disclosure, any combination of the various layers and sublayers of the III-N layer stack 124 may be collectively referred to as a III-N layer (or III-N semiconductor layer), which may extend over the semiconductor substrate 120, including a guard ring region (not specifically shown in this Figure) that may surround the device region 100B, as well as a scribe lane region (not specifically shown in this Figure) associated with the semiconductor device 199.

In some arrangements, a surface passivation layer 132 may be deposited over the barrier layer 126 using suitable dielectric materials (e.g., silicon nitride (SiN)) and a deposition process (e.g., a low pressure chemical vapor deposition (LPCVD) process), which may be configured to optimize certain key parameters relating to device reliability and performance, e.g., time-dependent dielectric breakdown (TDDB), dynamic RDSOn, etc. In some arrangements, the surface passivation layer 132 may also be referred to as a first pre-metal dielectric (PMD) layer, which may have a thickness in a range from 20 nm to 100 nm.

A second PMD layer 134 may be formed over the surface passivation layer 132, where the second PMD layer 134 may have a thickness in a range from 0.5 μm to 5 μm and may be configured to provide dielectric isolation between source and drain potentials and to reduce capacitive coupling during operation of the GaN FET 197. In an example, the second PMD layer 134 includes silicon nitride (SiN) or silicon dioxide (SiO₂). Alternatively, the second PMD layer 134 may include plural layers, for example, a first layer of SiN followed by a second layer of SiO₂. Depending on implementation, the second PMD layer 134 (or its layers) may be formed by plasma enhanced chemical vapor deposition (PECVD) or by a high density plasma (HDP) deposition, in a low temperature process (e.g., at or below 300° C.). For purposes of the present disclosure, any combination of the various layers and sublayers of the first PMD layer 132 and the second PMD layer 134 may be collectively referred to as a first dielectric layer or stack that may extend over the semiconductor substrate 120, including the GR region surrounding the device region 100B and the scribe lane region associated with the semiconductor device 199, where the GR region may be processed for forming one or more guard rings as will be set forth further below.

Suitable contacts 131A, 131B may be formed through the dielectric layer 134 with respect to the GaN FET 197, where the contacts 131A, 131B may be coupled to respective metal interconnect structures 138A, 138B formed from a first metal layer 139 that may be provided as a first metallization level (e.g., MET1) of a multi-level interconnect arrangement of the semiconductor device 199.

In some implementations, a substrate contact structure 195 may be formed in a trench 140 having a depth 142 defined in a substrate contact region 125 of the semiconductor substrate 120, where the trench 140 may have a metal liner 144 and may extend through the III-N stack 124 and the PMD layers 132, 134 to the upper surface 129 of the substrate 120. The first metal layer 139 may also be patterned and etched to form a conductive interconnect component 138C of the substrate contact structure 195. An inter-level dielectric (ILD) layer and/or inter-metal dielectric (IMD) layer, each comprising one or more sublayers, cumulatively referred to as a first IMD layer 136 having a suitable thickness, may be formed over the first metal layer 139. Although not specifically shown in this Figure, appropriate conductive vias may be formed through a planarized first IMD layer 136 in order to provide conductive paths to an upper level metal layer, e.g., a second metallization level (e.g., MET2), of the multi-level interconnect arrangement of the semiconductor device 199, where additional ILD or IMD layers and subsequent metal layers may be provided depending on implementation.

Additional details regarding the formation of GaN FET devices having suitable substrate contacts may be found in the following U.S. Patent Applications: (i) application Ser. No. 18/345,939, filed Jun. 30, 2023; and (ii) application Ser. No. 18/400,672, filed Dec. 29, 2023; each of which is incorporated by reference herein in its entirety for all purposes, which may be individually and/or collectively referred to as “incorporated disclosures.”

For purposes of the present disclosure, any combination of the various layers and sublayers of the IMD layers of the semiconductor device 199 may be collectively referred to as a second dielectric layer or stack that may extend over the semiconductor substrate 120, including the guard ring region surrounding the device region 100B and the scribe lane region associated with the semiconductor device 199. As will be set forth further below, a variety of GR structures may be provided in the guard ring region, where a GR structure may include a stack of metal structures formed over a trench that extends through at least the III-N semiconductor layer and into the substrate 120. Moreover, the metal structures may comprise various form factors, e.g., plates having respective thicknesses, that may be interconnected by vertical members formed through the IMD layers so as to facilitate providing appropriate crack arresting capability during singulation. Depending on implementation, various aspects and features relating to the fabrication of example GR structures may be integrated within a process flow for manufacturing III-N devices as set forth in the incorporated disclosures, without limitation.

Although the discussion that follows is directed primarily to examples based on GaN, the disclosed devices and methods are not so limited. In some implementations, the layers of a III-N stack may comprise a composition having the formula AlₓIn_{Y}Ga_{(1-X-Y)}N, where X, Y and (1-X-Y) refer to relative portions of aluminum, indium and gallium, respectively. In some additional and/or alternative implementations, the layers may comprise B_{w}AlₓIn_{y}Ga_{z}N materials, in which w, x, y and z each has a suitable value between zero and one (inclusive). The reference herein to B_{w}AlₓIn_{y}Ga_{z}N or a B_{w}AlₓIn_{y}Ga_{z}N material may refer to a semiconductor material having nitride and one or more of boron, aluminum, indium and gallium or a sub-combination thereof. Examples of B_{w}AlₓIn_{y}Ga_{z}N materials include GaN, AlN, AlGaN, AlInGaN, InGaN, and bAlInGaN, by way of illustration. A B_{w}AlₓIn_{y}Ga_{z}N material may include other materials besides nitride, boron, aluminum, indium and/or gallium. For example, a B_{w}AlₓIn_{y}Ga_{z}N material may be doped with a suitable dopant such as silicon and germanium.

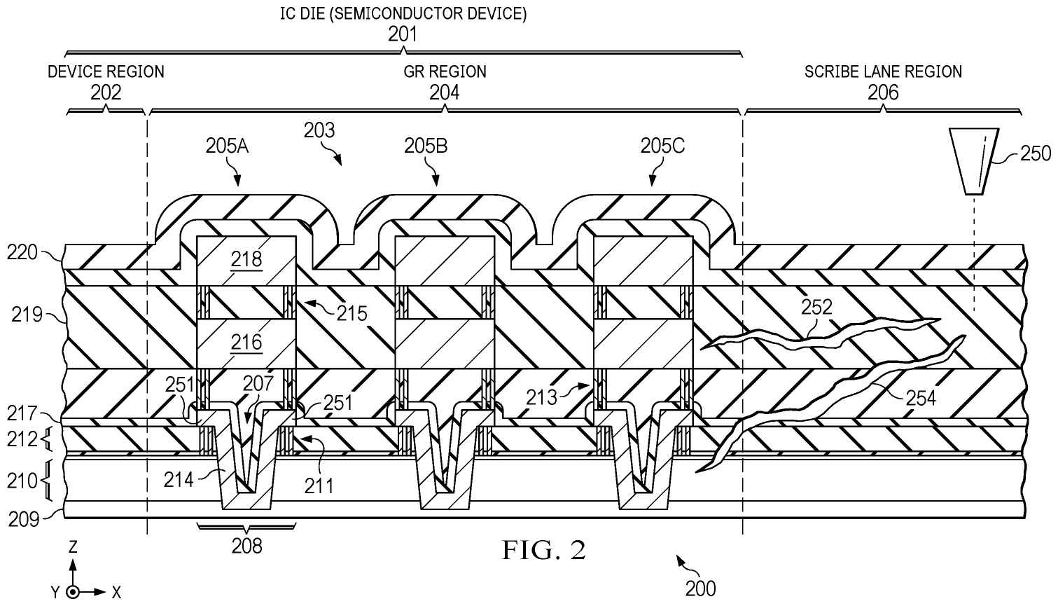

FIG. 2 depicts a cross-sectional view of a semiconductor wafer portion 200 including an unsingulated IC die with a GR structure configured to arrest crack propagation from a scribe lane region toward a device region of the IC die according to some examples of the present disclosure. As illustrated, an unsingualated IC die 201 of the wafer portion 200 includes a device region 202, which in some examples is representative of the device region 100B of FIG. 1B that may include one or more GaN devices as described above. A guard ring (GR) region 204 surrounding the device region 202 may include an example GR structure 203 containing one or more guard rings 205A-205C fabricated in accordance with a non-limiting implementation option provided herein. As noted previously, various GaN and dielectric layers and/or sublayers formed in the device region 202 may extend over a semiconductor substrate 209 of the semiconductor wafer portion 200, including the GR region 204 surrounding the device region 202 and abutting a scribe lane region 206 (e.g., surrounding the GR region 204). The scribe lane region 206 may receive a dicing edge (or saw) or laser beam 250 during singulation, which may generate mechanical forces that can cause cracks 252, 254 through the GaN layers and/or the overlying dielectric layers of the scribe lane region 206. The cracks 252, 254 may propagate into the device region 202 absent the GR structure 203 resulting in undesirable consequences for the IC die.

By way of example, a GaN layer stack 210 and a first dielectric layer 212 are illustrated, which are roughly analogous to the GaN layer stack 124 and the PMD layers 132/134 of FIG. 1B. Focusing on GR 205A as a representative guard ring in this particular example, a discontinuity 208 comprising a trench 207 may be formed through the GaN layer stack 210 and the first dielectric layer 212, respectively. The trench 207 may surround the device region 202 (e.g., along the X- and Y-axes on a horizontal plane parallel to a major surface of the semiconductor substrate 209, analogous to the upper surface 129 shown in FIG. 1B) and extend into the semiconductor substrate 209 (e.g., along the Z-axis normal relative to the major surface of the semiconductor substrate 209). In the particular example of FIG. 2, a metal liner 214 formed of a first metal layer (e.g., MET1) may be provided along the interior surfaces of the trench 207. As illustrated, the metal liner 214 may include a portion or an extension forming a collar or flange 251 that may extend over a surface of the first dielectric layer 212. A nitride layer 217 may be formed over the surface of the first dielectric layer 212 as well as the metal liner 214.

In one arrangement, a plurality of contacts or posts 211 (e.g., comprising tungsten) may be formed through the first dielectric layer 212 for coupling with the metal liner extension 251 and extending to an upper surface of the GaN layer 210. As illustrated in this particular example, a metal plate 216 formed of a second metal layer (e.g., MET2) may be formed over the trench 207 and a metal plate 218 formed of a third metal layer (e.g., MET3) may be formed over the metal plate 216, where one or more ILD/IMD layers, collectively referred to as IMD 219 and laterally extending from the device region 202, may be processed for providing separation between the different metal layers. Further, a metal layer structure of a metal level may be coupled to a next level metal layer structure by way of one or more conductive vias (e.g., copper, aluminum, etc.) formed through a corresponding IMD layer, e.g., as illustrated by vias 213 coupled between the metal liner extension 251 of MET1 and metal plate 216 of MET2 and vias 215 coupled between metal plate 216 of MET2 and metal plate 218 of MET3, in the particular example of FIG. 2. A protective dielectric layer 220 (e.g., a protective overcoat (PO) layer) comprising suitable dielectric materials, e.g., SiN, SiO_{X}, etc., may be formed over the device region 202, the GR region 204 including GRs 205A-205C, and the scribe lane region 206. The protective dielectric layer 220 may comprise multiple layers/sublayers that may be planarized in some implementations.

In some examples, the fabrication of GR structures configured as crack arresting structures as set forth herein may be integrated with a fabrication flow for forming substrate contacts in III-N devices, e.g., including the formation of trenches/discontinuities, metallization, via/contact formation, and the like, so as to advantageously leverage process flow synergies. In other examples, example GR structures of the present disclosure may be fabricated independently regardless of whether a substrate contact formation flow is involved. Further, the fabrication flows of example GR structures of the present disclosure provide versatility in integrating the GR formation at different stages of a III-N process flow, such that various configurations of GR structures may be implemented at a manufacturing facility.

Set forth below are additional details with respect to the examples described above as well as additional, alternative and/or optional implementations according to further examples.

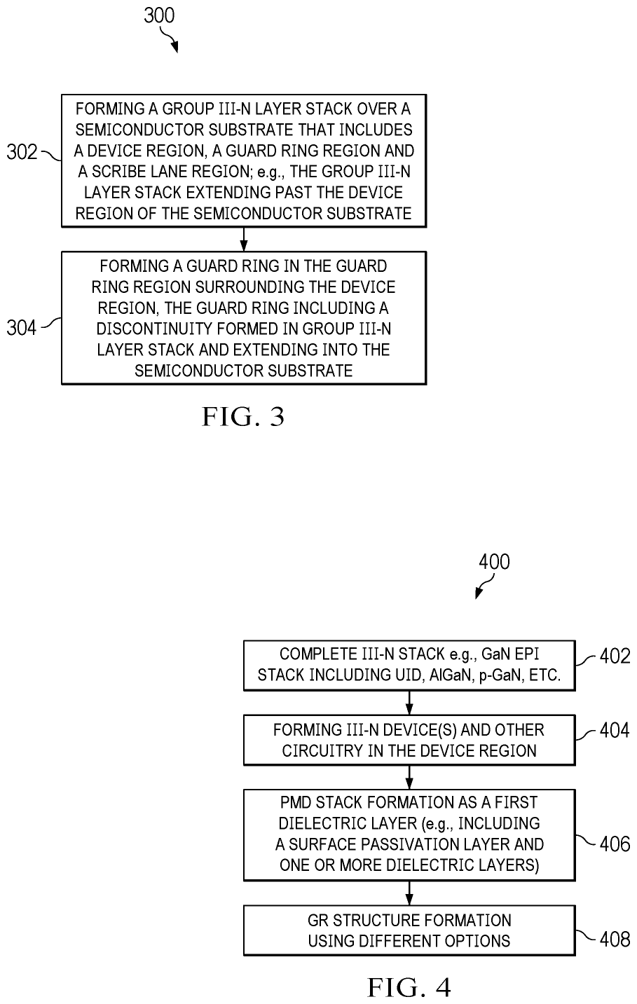

FIG. 3 is a flowchart of a method 300 of fabricating a semiconductor device including a GR structure according to some examples. In one arrangement, the method 300 may commence with forming a Group III-N layer stack, or simply a “III—N layer (or III-N semiconductor layer)” as discussed previously, over a semiconductor substrate that includes a device region, a guard ring region and a scribe lane region. The III-N layer may extend past the device region of the semiconductor substrate, as set forth at block 302. Moreover, the III-N layer may extend throughout the guard ring region surrounding the device region and into the scribe lane region surrounding the guard ring region. Depending on implementation and device application, the III-N layer may include plural layers, having an overall thickness of about 3 μm to 5 μm. At block 304, a guard ring may be formed in the guard ring region surrounding the device region, where the guard ring may include a discontinuity formed in the III-N layer and extended into the semiconductor substrate.

As will be set forth below, the discontinuity may comprise a trench (also referred to as a GaN trench or a GR trench in some examples) extending into the semiconductor substrate by a desired amount (e.g., around 1.0 μm to 2.0 μm or less), which may be fabricated by a suitable trench etch process having an over-etch endpoint in the substrate. Depending on a thickness of an overlying dielectric layer formed over the III-N layer, e.g., a first dielectric layer or stack having a thickness of about 800 nm to 1200 nm, an example GaN trench may have a depth of about 10 μm to 20 μm, and may have a top width of about 3 μm to 5 μm that may taper to a smaller width at the bottom of the trench. In some examples, the GR trench formation may follow a process flow similar to that of substrate contact formation as set forth in one or more incorporated disclosures referenced above previously.

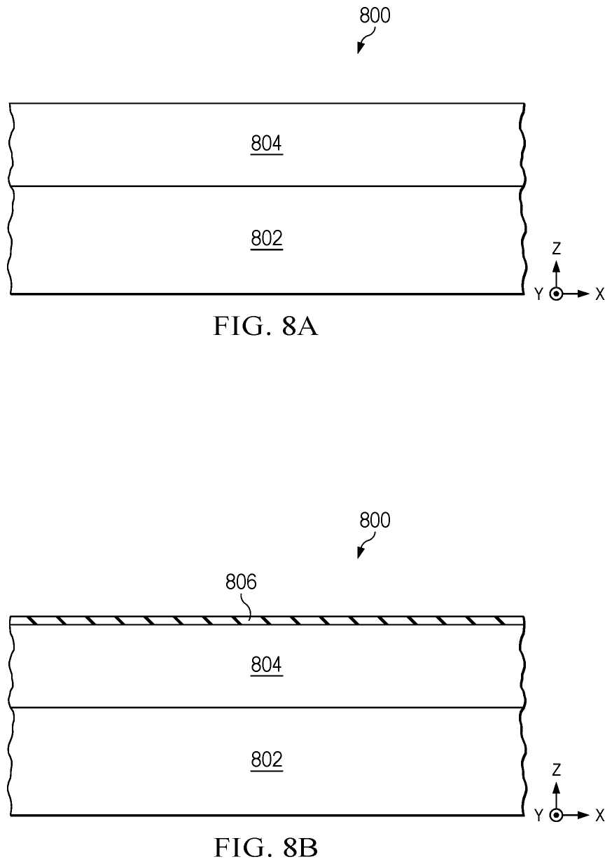

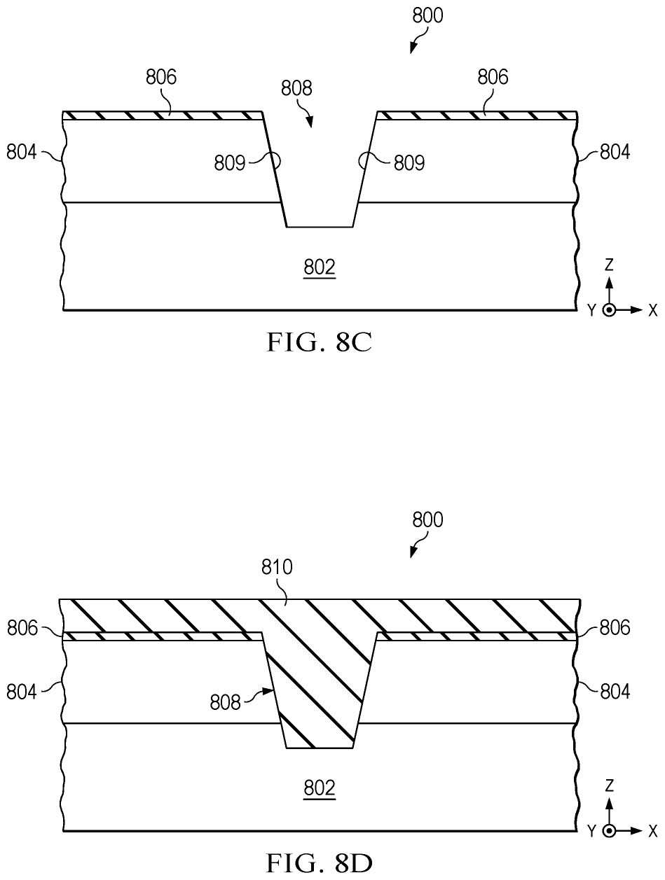

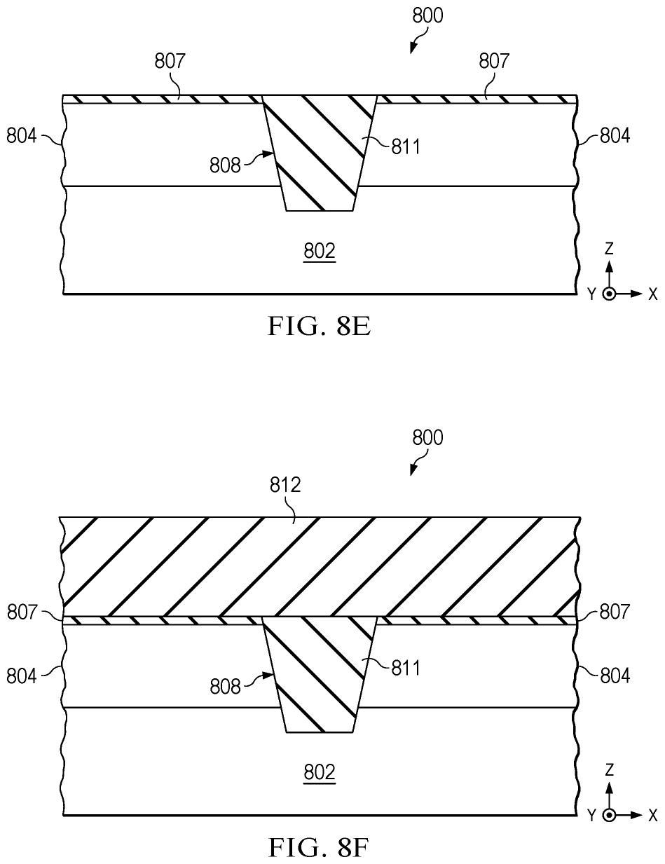

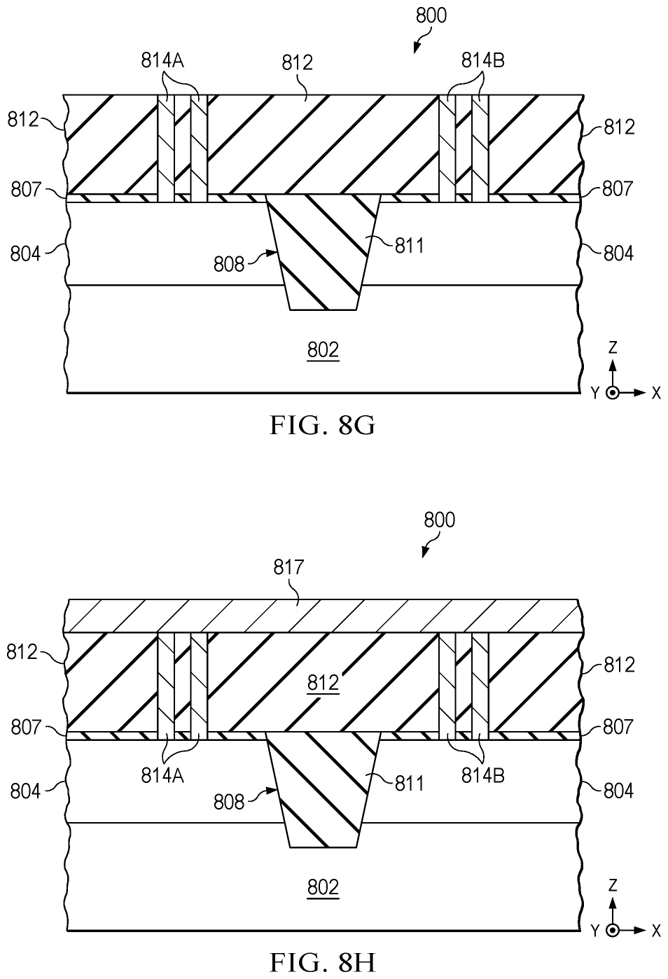

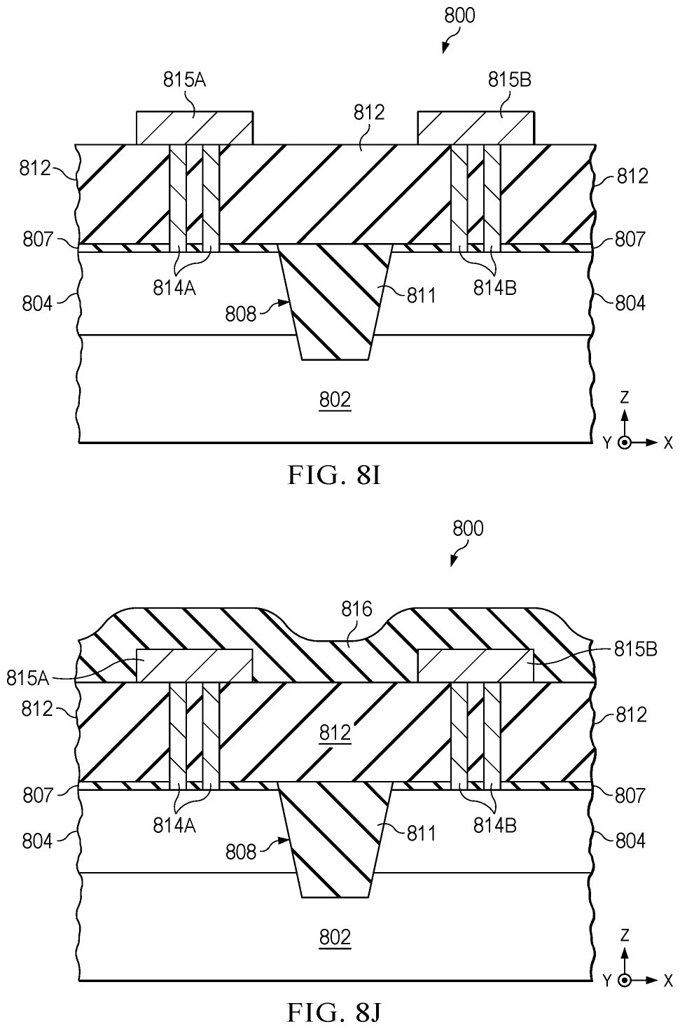

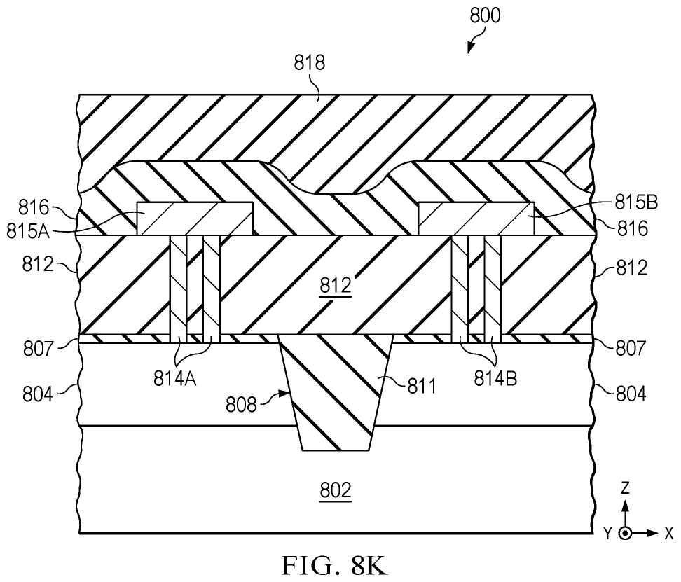

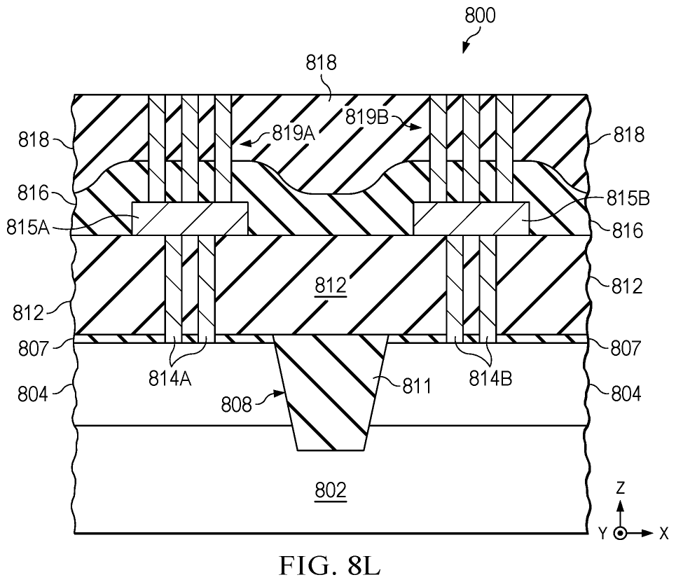

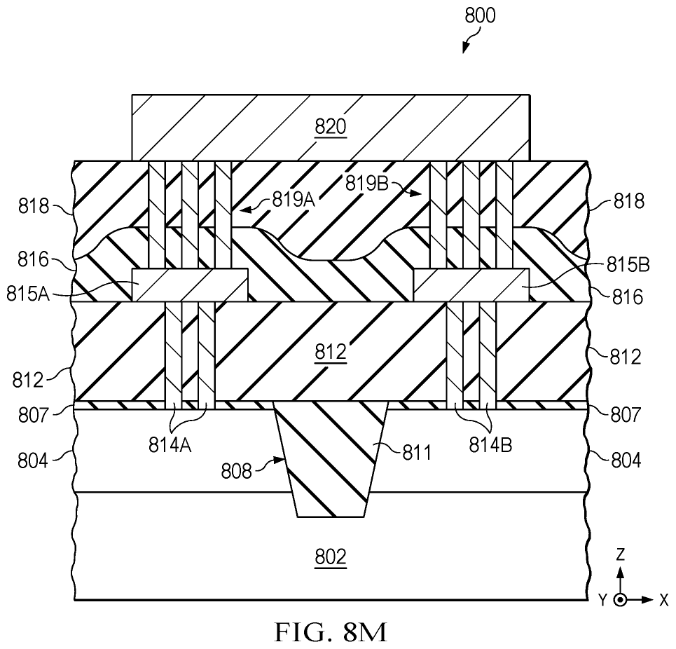

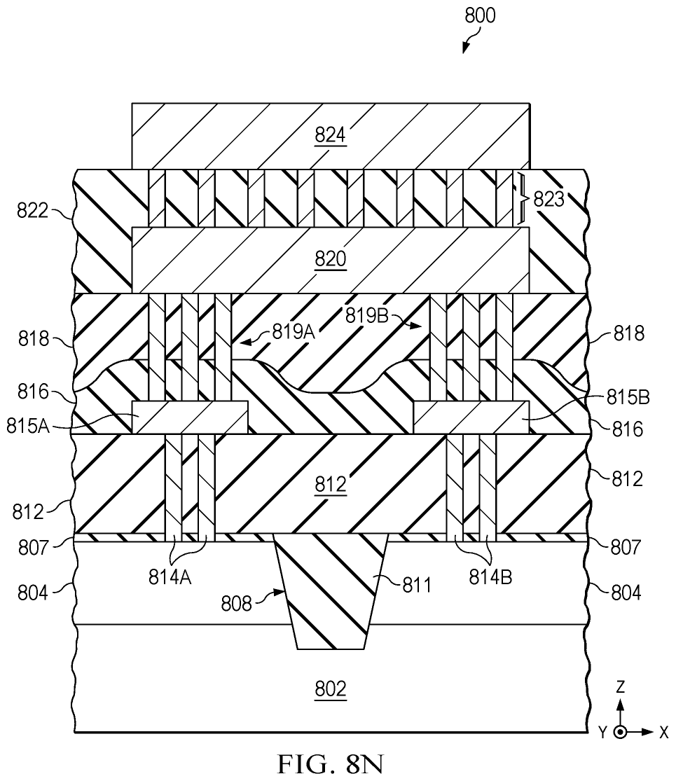

Depending on implementation, a GR region may include one or more GR structures, e.g., three (3) GR structures as illustrated in FIG. 2 described above, where each GR structure may include a corresponding discontinuity in the form of a trench. Moreover, examples set forth herein illustrate the formation of a trench at different fabrication stages of a flow. In some arrangements, trenches may be formed immediately after the III-N epi growth, prior to forming III-N devices. In some arrangements, trenches may be formed after forming a passivation layer (e.g., first dielectric material 806 described with reference to FIG. 8B), prior to forming III-N devices. In some arrangements, the trench may be formed after forming III-N devices, following various stages of dielectric layers. Depending on implementation, after forming III-N devices, GR trenches may be formed after a PMD stage (e.g., before a first metal layer), a first ILD layer (e.g., before a second metal layer, a second ILD layer (e.g., before a third metal layer), and so on.

In some examples, the formation of a GaN trench may be performed after forming various GaN devices in a device region of the semiconductor device. Subsequently, the remaining stages of forming a GR metal stack may be performed using a variety of optional implementations and combinations thereof. In other examples, the formation of a GaN trench may be performed before forming the GaN devices and the formation of a first dielectric layer thereover.

FIG. 4 is a flowchart of a method 400 of fabricating a semiconductor device including a GR structure (e.g., a GaN trench) formed after forming III-N devices (e.g., transistors, diodes, etc.) according to some examples. At block 402, a III-N layer may be formed including layers/sublayers such as a UID layer, an AlGaN barrier layer, a p-GaN layer, as well as other layers comprising a graded region, etc., which may have a suitable overall thickness as set forth above. At block 404, various III-N devices may be formed in a device region of the semiconductor device. In some arrangements, the III-N devices may be fabricated according to the process flows set forth in the incorporated disclosures referenced above. At block 406, a first dielectric layer, including, e.g., a first PMD or surface passivation layer, a second PMD layer that may be thicker than the first PMD layer, etc., may be formed over the GaN devices. At block 408, one or more GRs, each including a discontinuity, may be fabricated as part of forming a GR structure around the device region of the semiconductor device (or an IC die) in accordance with different implementation options as will be described in additional detail further below. In some sections of the description, reference may be taken to respective flowcharts as well as various cross-sectional views depicting the formation of a GR structure of a semiconductor device (or an IC die) at several process stages of a flow where the cross-sectional views are generally illustrative of the process steps of the respective flowcharts.

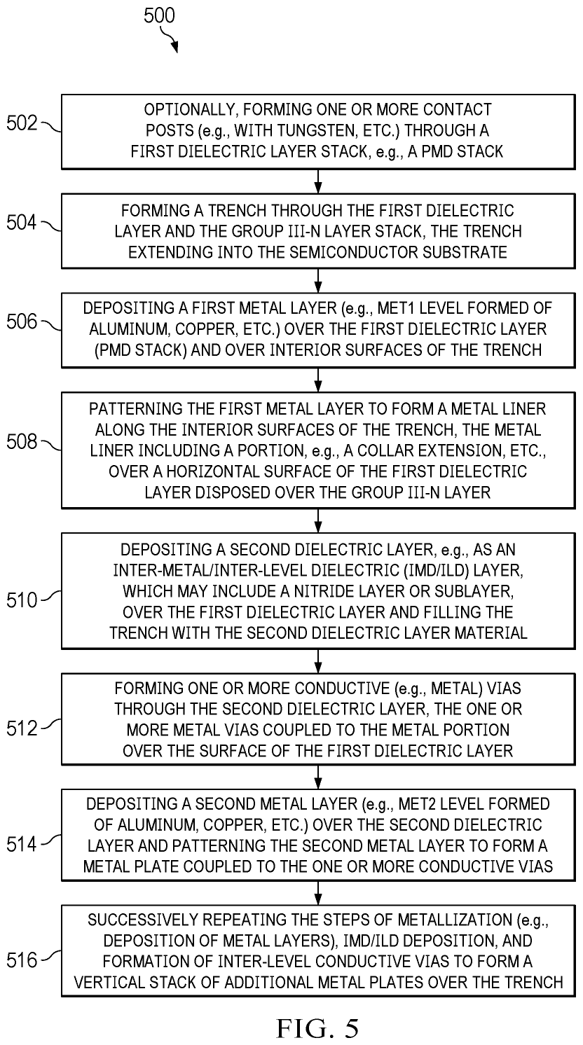

FIG. 5 is a flowchart illustrative of additional details relating to a method 500 of fabricating a semiconductor device including a GR structure (e.g., a GaN trench) formed after III-N device formation, which may form a particular implementation option of block 408 set forth above. For example, the GR structure may include a discontinuity comprising a trench with an interior metal liner according to some examples. As illustrated, the method 500 may include an optional stage (at block 502) for forming one or more contact posts (or contacts, e.g., filled with tungsten, etc.) through a first dielectric layer stack, e.g., a PMD stack, formed in block 406 of FIG. 4. At block 504, a trench of suitable dimensions may be formed through the first dielectric layer and the III-N layer, where the trench may extend into the semiconductor substrate by a suitable substrate over-etch process as noted above.

At block 506, a first metal layer (e.g., MET1 formed of aluminum, copper, etc.) may be formed over the first dielectric layer and over interior surfaces of the trench. Depending on implementation, damascene or non-damascene processes may be used for forming metal layers and other conductive features of the example GR structures herein. In some arrangements, a sputter process, a reactive sputter process, or an atomic layer deposition (ALD) process may be used for forming the first metal layer. At block 508, the first metal layer may be patterned (e.g., using reactive ion etch (RIE) or plasma etching) to form a metal liner along the interior surfaces of the trench. In some arrangements, the metal liner may include a portion (e.g., an external portion, a collar or a collar extension, flange) that extends over a horizontal surface of the first dielectric layer disposed over the III-N layer and forming an upper rim of the trench, as noted previously. In some arrangements where the contacts have been formed through the first dielectric layer, the metal liner portion may be dimensioned so as to extend over the contacts.

At block 510, a second dielectric layer may be deposited, e.g., as an inter-metal/inter-level dielectric (IMD) layer, which may include a nitride layer or sublayer that may be deposited before an oxide layer, over the first dielectric layer stack. The trench may be filled with the second dielectric layer material. At block 512, one or more conductive (e.g., metal) vias may be formed through the second dielectric layer, where the one or more conductive vias may be coupled to the metal portion over the surface of the first dielectric layer. At block 514, a second metal layer (e.g., MET2 formed of aluminum, copper, etc.) may be formed over the second dielectric layer, e.g., similar to the formation of the first metal layer as set forth above. Thereafter, the second metal layer may be patterned (e.g., using RIE/plasma processes) to form a metal plate coupled to the one or more conductive vias. Depending on implementation, the steps of metallization (e.g., deposition of metal layers), IMD/ILD deposition, and formation of inter-level conductive vias may be successively repeated, e.g., based on the number of metallization levels used for forming a multi-level interconnect system for the semiconductor device (or the IC die), to form a vertical stack of additional metal plates over the trench where a metal plate of one level may be coupled to an adjacent metal level by a corresponding set of conductive vias as set forth at block 516.

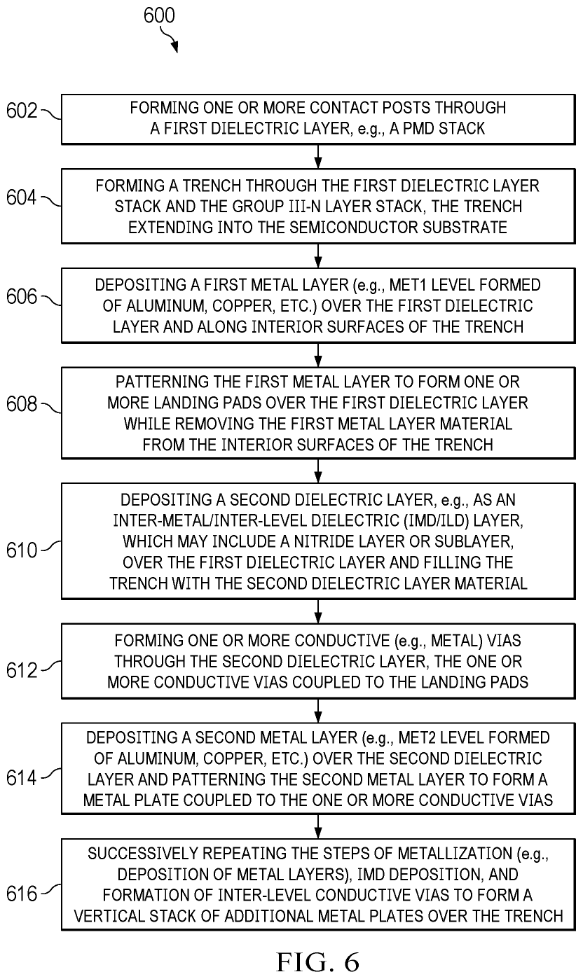

FIG. 6 is a flowchart illustrative of additional details relating to a method 600 of fabricating a semiconductor device including a GR structure (e.g., a GaN trench) formed after the formation of III-N devices, which may form another particular implementation option of block 408 set forth above. For example, the GR structure may include a discontinuity (e.g., a GaN trench) comprising a trench that is devoid of a metal liner according to some examples. Similar to the example set forth above, the method 600 may include a block 602 where one or more contact posts may be formed through a first dielectric layer, e.g., a PMD stack, that may be deposited at part of block 406. At block 604, a trench of suitable dimensions may be formed through the first dielectric layer stack and the III-N layer, the trench extending into the semiconductor substrate.

At block 606, a first metal layer (e.g., MET1 formed of aluminum, copper, etc.) may be formed over the first dielectric layer and along interior surfaces of the trench using processes similar to the metal layer formation processes set forth above. In this example, the first metal layer may be patterned and etched to form one or more landing pads (or simply “pads”) over the first dielectric layer, where the pads overlie the contacts formed through the first dielectric layer, while removing the first metal layer material from the interior the surfaces of the trench (block 608). At block 610, a second dielectric layer may be deposited, e.g., as an inter-metal/inter-level dielectric (IMD) layer, which may include a nitride layer or sublayer that may be deposited before an oxide layer, over the first dielectric layer. The trench may be filled with the second dielectric layer material, similar to the foregoing examples set forth in reference to the method 500.

At block 612, one or more conductive (e.g., metal) vias may be formed through the second dielectric layer, where the one or more conductive vias may be coupled to the landing pads formed on the first dielectric layer. At block 614, a second metal layer (e.g., MET2 formed of aluminum, copper, etc.) may be formed over the second dielectric layer, where the second metal layer may be patterned and etched to form a metal plate coupled to the one or more conductive vias. Similar to block 516, block 616 may involve successively repeating the steps of metallization (e.g., deposition of metal layers), IMD deposition, and formation of inter-level conductive vias to form a vertical stack of additional metal plates over the trench.

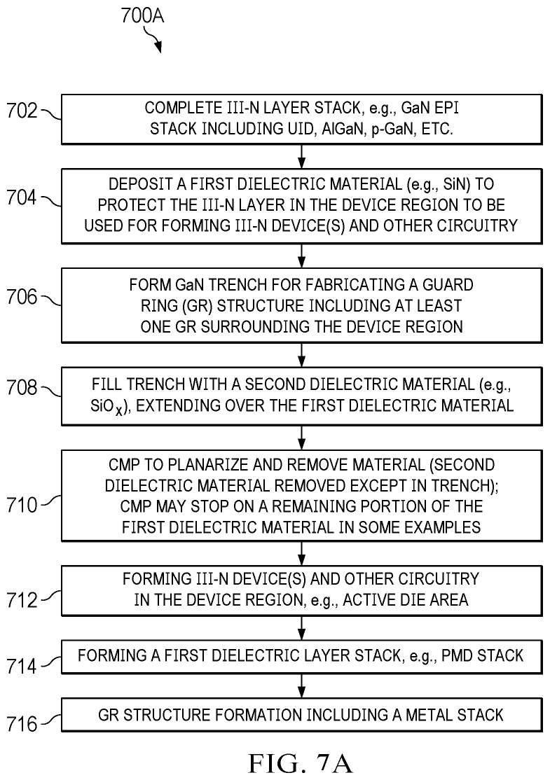

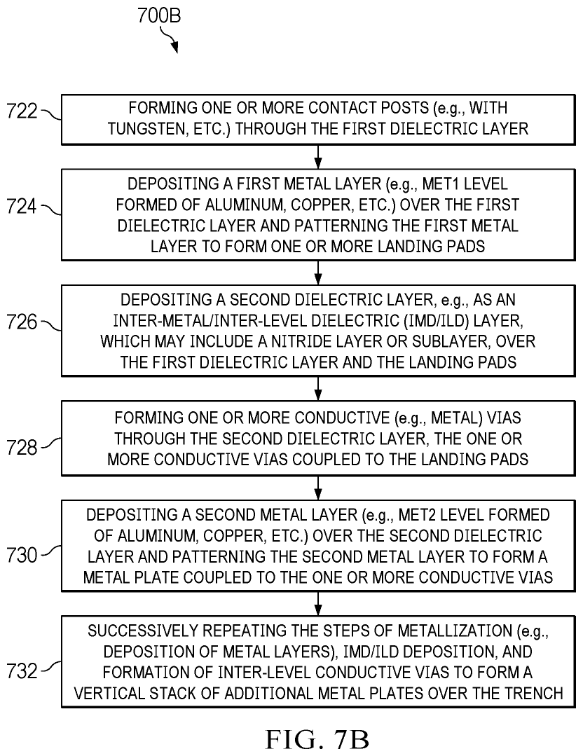

FIGS. 7A and 7B depict flowcharts relating to representative methods of fabricating a semiconductor device including a trench for a GR structure formed before the formation of III-N devices in a device region of the semiconductor device (or IC die) according to some examples. The trench may be devoid of a metal liner. Method 700A shown in FIG. 7A relates to an overall process flow for forming a GR structure surrounding the device region. Method 700B shown in FIG. 7B is illustrative of additional details with respect to a particular example of GR structure formation that may be integrated with a portion of the method 700A.

At block 702, a III-N layer may be formed over a semiconductor substrate of the semiconductor device, where the III-N layer includes layers/sublayers such as a UID layer, an AlGaN barrier layer, a p-GaN layer, as well as other layers comprising a graded region, etc., as set forth previously. Before proceeding with the formation of III-N devices in a device region of the semiconductor device (or IC die), a first dielectric material (e.g., SiN) having a suitable thickness may be deposited over the III-N layer (e.g., to protect the III-N layer in the device region to be used for forming III-N device(s) and/or other circuitry in subsequent operations), as set forth at block 704. At block 706, at least one trench (e.g., GaN trench) having suitable dimensions may be formed in a GR region surrounding the device region of the semiconductor device.

At block 708, the trench may be filled with a second dielectric material (e.g., SiO_{X}), which may extend over the first dielectric material as an overburden layer. At block 710, the overburden second dielectric material as well as at least a portion of the first dielectric material may be removed and/or planarized using, e.g., a chemical mechanical polish (CMP) process and/or an etch-back process. In some examples, the CMP process may be configured to remove the entire overburden and land on a remaining portion of the first dielectric material, which forms a layer overlying the III—N layer and the trench filled with the second dielectric material. In some examples, the CMP process may be configured to remove the first dielectric material completely, thus landing on a surface of the III-N layer, with the remaining second dielectric material filling the trench. Thereafter, the method 700A may proceed with forming III-N devices in the device region of the semiconductor device (block 712), followed by forming one or more PMD layers as a first dielectric layer (block 714) that may extend over the device region, the GR region and the scribe lane region as described previously. Subsequently, a GR metal stack may be formed over the filled trench for fabricating a completed GR structure in the GR region of the semiconductor device (or IC die), as set forth at block 716.

In some arrangements, the method 700B of FIG. 7B may be performed as a particular implementation of block 716. Similar to some of the examples set forth above, the method 700B may commence with a block 722 for forming one or more contact posts (e.g., with tungsten, etc.) through a first dielectric layer, e.g., a PMD stack, that may be formed at part of block 714. At block 724, a first metal layer (e.g., MET1 formed of aluminum, copper, etc.) may be formed over the first dielectric layer using processes similar to the metal layer formation processes set forth above. Subsequently, the first metal layer may be patterned and etched to form one or more landing pads (or simply “pads”) over the first dielectric layer and overlie the contacts formed therethrough. At block 726, a second dielectric layer may be deposited, e.g., as an inter-metal/inter-level dielectric (IMD) layer, which may include a nitride layer or sublayer that may be deposited before an oxide layer, over the first dielectric layer and the pads.

At block 728, one or more conductive (e.g., metal) vias may be formed through the second dielectric layer, where the one or more conductive vias may be coupled to the landing pads formed on the first dielectric layer. At block 730, a second metal layer (e.g., MET2 formed of aluminum, copper, etc.) may be formed over the second dielectric layer. Subsequently, the second metal layer may be patterned and etched to form a metal plate coupled to the one or more conductive vias. Similar to the examples set forth previously, the method 700B may include successively repeating the steps of metallization (e.g., deposition of metal layers), IMD deposition, and formation of inter-level conductive vias to form a vertical stack of additional metal plates over the trench that is completely filled with a dielectric material (e.g., SiO_{X} as set forth in FIG. 7A).

Various cross-sectional views depicting the formation of a GR structure of a semiconductor device at several process stages of a flow will be set forth below, where the cross-sectional views are generally illustrative of the process steps of the respective methods described in detail above.

Turning to FIGS. 8A-80, depicted therein are cross-sectional views roughly corresponding to aspects of a combination of process steps of the methods 700A, 700B shown in FIGS. 7A and 7B, respectively. FIG. 8A depicts a process stage where an III-N layer 804 is epitaxially formed over a semiconductor substrate 802 of a semiconductor device 800, corresponding to aspects of block 702. FIG. 8B depicts a process stage where a first dielectric material 806 is deposited over the III-N layer 804, corresponding to aspects of block 704. FIG. 8C depicts a process stage after forming a trench 808 through the first dielectric material 806 and the III-N stack 804, and with interior surfaces 809 extending into the semiconductor substrate 802, corresponding to aspects of block 706. FIG. 8D depicts a process stage where the trench 808 is filled with a second dielectric material 810, which may extend over the first dielectric material 806 as an overburden layer, corresponding to aspects of block 708.

FIG. 8E depicts a process stage roughly corresponding to the operations set forth at block 710. As shown, after removing the overburden second dielectric material as well as a portion of the first dielectric material (e.g., by CMP, by etch-back), a remaining layer 807 of the first dielectric material 806 may be formed that overlies the III-N layer 804 and the trench 808 is filled with a filler 811 of remaining second dielectric material 810. Subsequently, various III-N devices may be formed in a device region (not shown in FIGS. 8A-80) of the semiconductor device 800. In some examples, the III-N devices may comprise devices formed according to a fabrication flow set forth in the incorporated disclosures referenced previously, without limitation. FIG. 8F depicts a process stage after forming the III-N devices in the semiconductor device 800, where a PMD stack 812 is formed as a first dielectric layer over the III-N devices. In some examples, the first dielectric layer may include a surface passivation layer provided in the fabrication of III-N devices as noted above, corresponding to aspects of block 714.

FIG. 8G depicts a process stage after forming one or more contacts 814A, 814B, corresponding to aspects of block 722, that extend through the first dielectric layer 812 and the remaining layer 807 of the first dielectric material 806. The contacts 814A, 814B land on a surface of the III-N layer. Depending on implementation, the contacts 814A, 814B may be organized into one or more rows or columns, where the rows/columns of contacts may be formed on and along each or either side of the filled trench 808, each contact having a thickness (e.g., width, diameter or a similar horizontal dimension along the X-axis) less than around 100 nm and a height of about 1000 nm in some examples.

FIG. 8H depicts a process stage where a first metal layer 817 (e.g., as part of MET1 metallization) is formed over the first dielectric layer 812, which is patterned to form landing pads 815A, 815B as depicted in FIG. 8I for coupling with the contacts 814A, 814B. By way of example, the pads 815A, 815B may have a thickness of about 100 nm to 500 nm and, depending on the metallization process used, may include aluminum, copper, etc., as well as one or more suitable barrier layers, corresponding to aspects of block 724. FIG. 8J depicts a process stage where a SiN layer 816 is optionally deposited over the first dielectric layer 812 and the pads 815A/815 of the semiconductor device 800. An ILD/IMD layer 818 comprising oxide is deposited over the SiN layer 816 and planarized as depicted in FIG. 8K. In some arrangements, the SiN layer 816 may be provided as an optional sublayer of a second dielectric layer including the ILD/IMD layer 818, corresponding to aspects of block 726.

FIG. 8L depicts a process stage after forming one or more conductive vias 819A and 819B through the second dielectric layer 818, including any sublayers 816, where the conductive vias 819A, 819B are coupled to respective pads 815A, 815B disposed over the first dielectric layer 812, corresponding to aspects of block 728. In some arrangements, the conductive vias 819A, 819B may each have a thickness (e.g., width, diameter or a similar horizontal dimension along the X-axis) around 200 nm to 500 nm and a height greater than of about 2 μm, and may be disposed on each side of the filled trench 808 similar to the placement of the contacts 814A, 814B. Whereas it is expected that providing multiple contacts/vias on each side of the filled trench may provide more structural stability and potentially greater crack arresting capability as a result, it is not a requirement for purposes of some example implementations herein. Depending on the metallization process used, the vias 819A, 819B may include aluminum, copper, etc., as well as one or more suitable barrier layers.

FIG. 8M depicts a process stage where a second metal layer is formed and patterned over the second dielectric layer 818 (e.g., as part of MET2 metallization) to form a metal plate 820, e.g., a first metal plate, coupled to the conductive vias 819A, 819B, corresponding to aspects of block 730. As before, the second metal layer and the metal plate 820 formed therefrom may include aluminum, copper, etc., in addition to any barrier layers. In some examples, the metal plate 820 may have a thickness around 3.0 μm to 5.0 μm. Whereas the metal plate 820 is depicted in the cross-sectional views as a planar member spanning over and coupled to the underlying conductive vias 819A, 819B, the metal plate 820 is representative of a transverse portion of a rectangular metal structure (e.g., a metal frame, a metal fence structure) disposed on a metal level plane and having a length along a horizontal axis (e.g., X-axis and/or Y-axis) surrounding a device region of the semiconductor device 800 as previously noted.

FIG. 8N depicts a process stage where a next level IMD/ILD layer 822 is deposited as a third dielectric layer over the metal plate 820, through which one or more conductive vias 823 may be formed similar to the conductive vias 819A and 819B. Further, a third metal layer may be formed and patterned over the third dielectric layer 822 (e.g., as part of MET3 metallization) to form a second metal plate 824 coupled to the conductive vias 823. Corresponding to aspects of block 732, the foregoing stages of metal layer deposition/patterning, deposition of dielectric layers and inter-level via formation may be repeated sequentially, resulting in a metal stack of multiple metal plates depending on the number of metallization levels used for forming the GR structure in an example implementation. Thereafter, a multi-layer protective dielectric structure (which may be referred to as a protective oxide (PO) structure), e.g., including a PO oxide layer 826 and a PO nitride layer 828, each having a suitable thickness, is formed over the resulting metal stack, e.g., including the metal plate 824, as well as associated dielectric layers 822, to complete the fabrication of the semiconductor device 800, as shown in FIG. 8O, which may be followed by a die separation stage involving mechanical or laser dicing.

In some implementations, PMD layer formation, metal layer deposition/patterning, deposition of ILD/IMD layers and inter-level via formation, etc., as set forth above may follow process flows similar to the process flows described in one or more incorporated disclosures referenced above previously. By way of example, a PMD layer may include multiple PMD sublayers. A first PMD sublayer may primarily include silicon nitride material, which may be formed by an LPCVD process to attain a hydrogen content less than 10 atomic percent. A second PMD sublayer may also primarily comprise silicon nitride material, which may be formed by a PECVD process and may be optionally planarized (e.g., CMP and/or etch-back). A third PMD sublayer may primarily comprise silicon oxide material, which may be formed by a PECVD process or an HDP process. In some examples, a first ILD/IMD layer may include primarily silicon oxide, and may be formed by a PECVD process or an HDP process. As noted previously, the first ILD/IMD layer may include a sublayer of silicon nitride (e.g., SiN 816), which may provide protection against moisture infiltration from the singulation lanes surrounding the GR regions of the semiconductor device 800. In some arrangements, some ILD/IMD layers may be planarized to facilitate the formation of a next level metal layer.

In some implementations, the contacts 814A, 814B formed through the PMD layers, e.g., provided as the first dielectric layer 812, may include an adhesion liner of titanium formed by a sputter process. In some implementations, the contacts 814A, 814B may include a barrier liner of titanium nitride on the adhesion liner, where the barrier liner may be formed by a reactive sputter process, an ALD process, etc. In some implementations, the contacts 814A, 814B may include a fill plug of tungsten on the barrier liner, formed by a metal organic chemical vapor deposition (MOCVD) process including reduction of tungsten hexafluoride. In some implementations, any overburden of the tungsten, barrier liner and adhesion liner on a top surface of the first dielectric layer may be removed by a CMP process, an etch-back process, or a combination of both. In some implementations, inter-level conductive vias, e.g., vias 819A/B and 823, may be formed of copper on a barrier liner, formed by a copper damascene process. In some implementations, vias 819A/B and 823 may be formed of aluminum formed in a non-damascene process. In some implementations, vias 819A/B and 823 may have a composition and a structure similar to the contacts set forth herein, and may be formed by a similar process sequence.

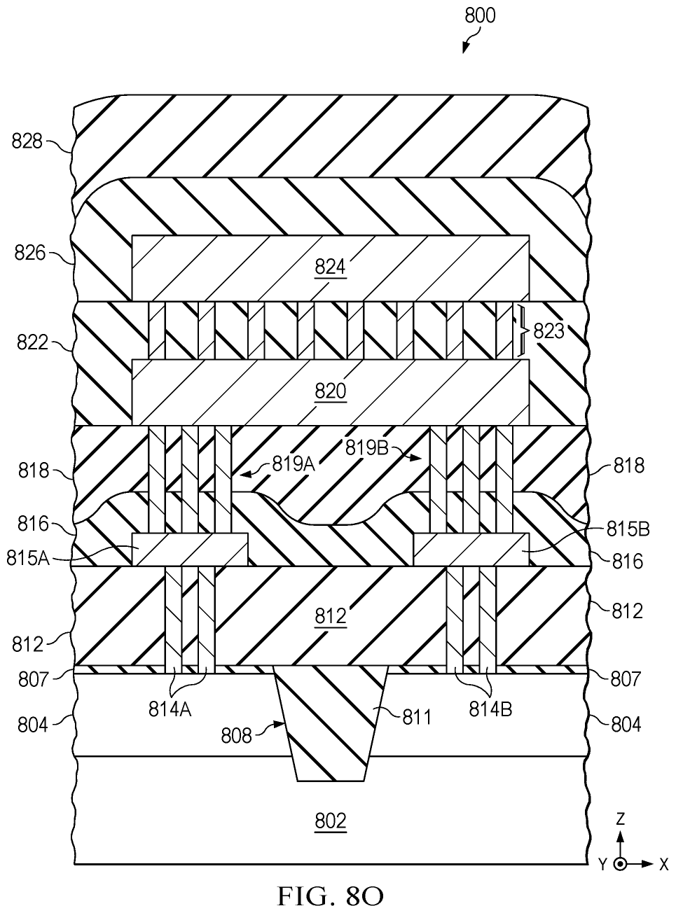

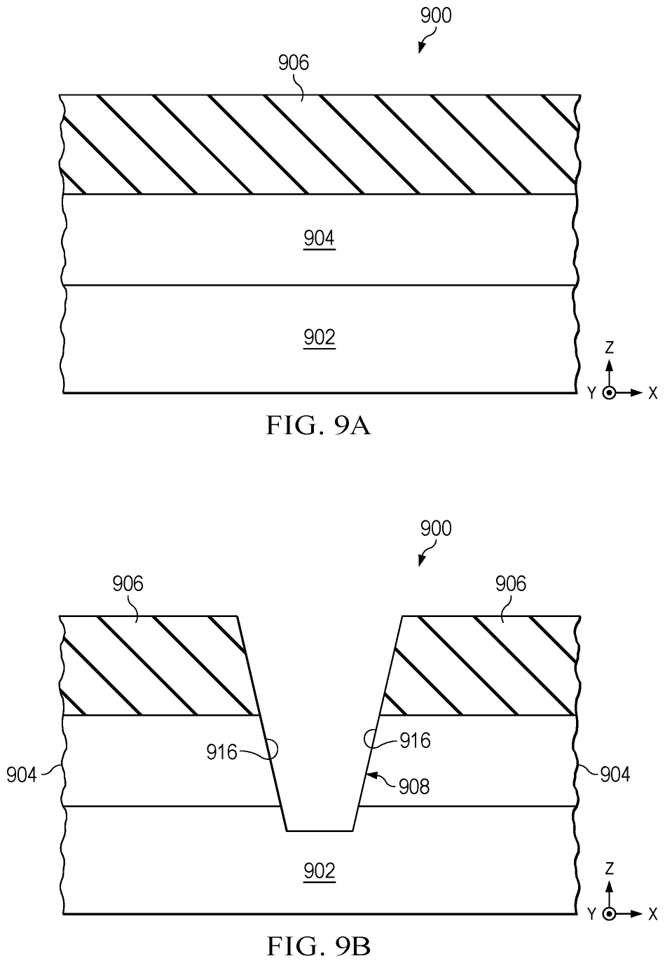

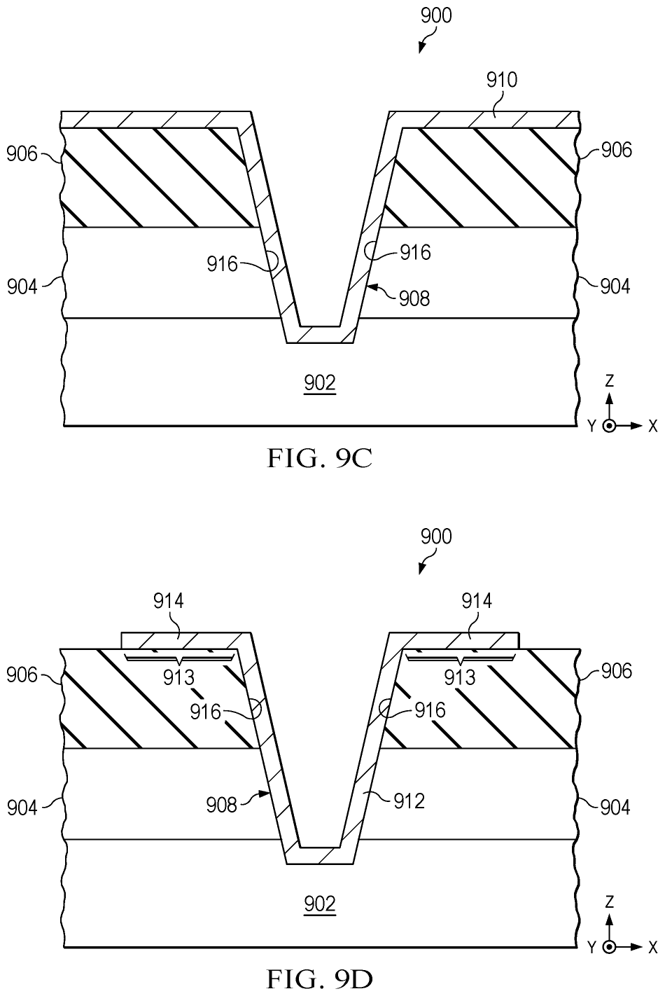

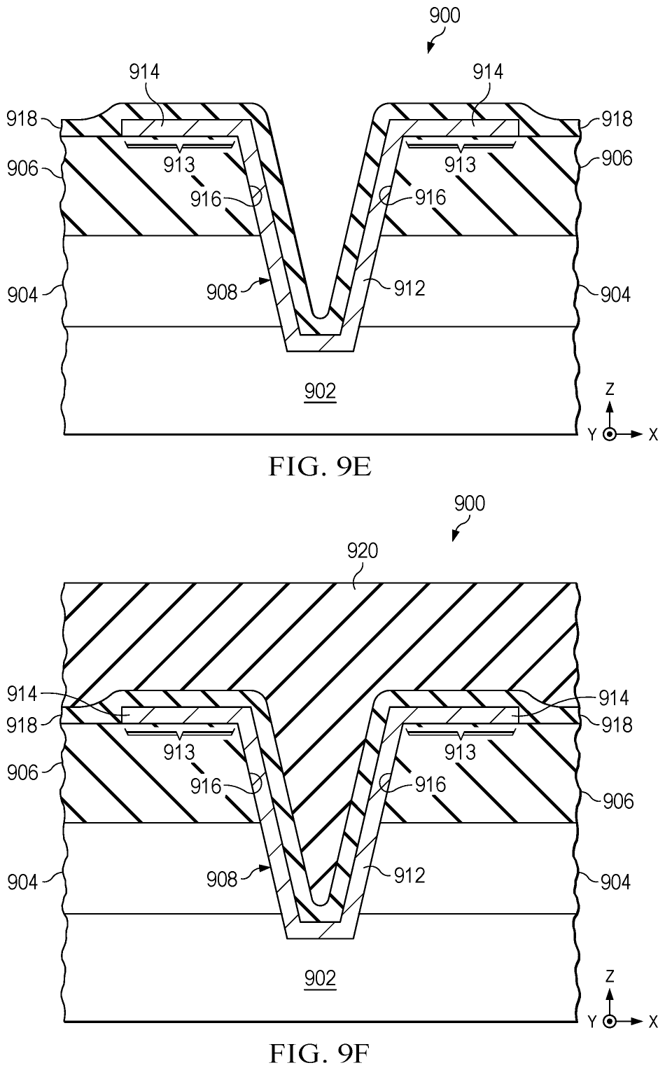

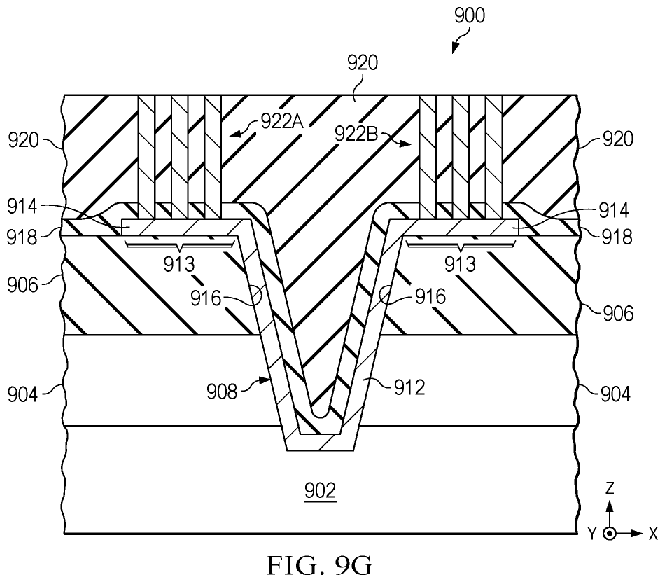

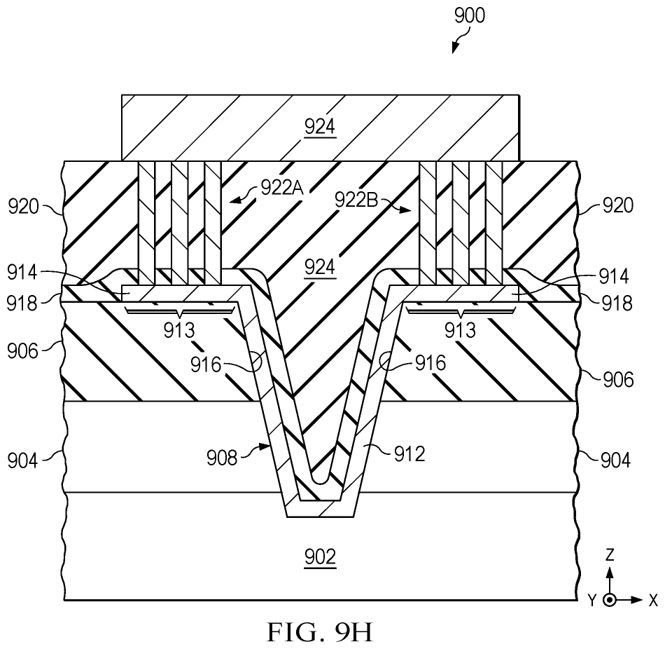

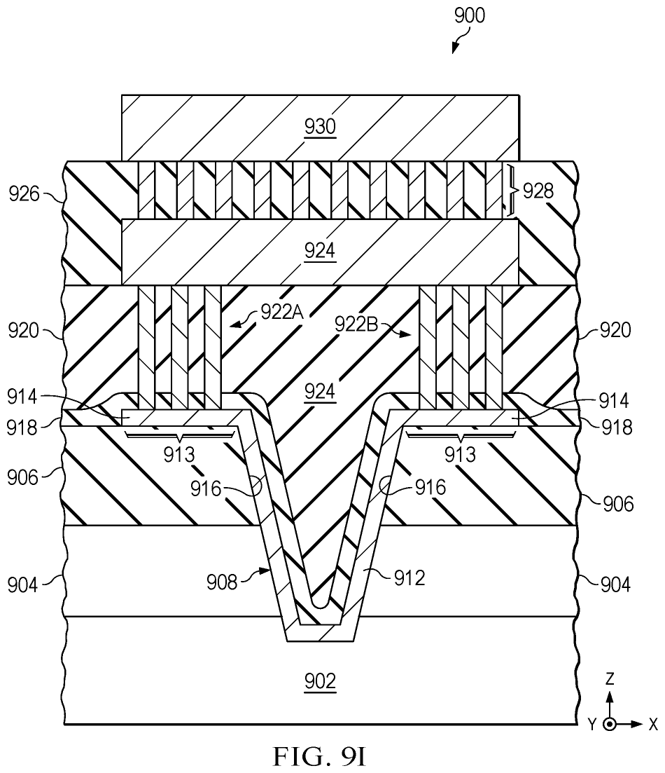

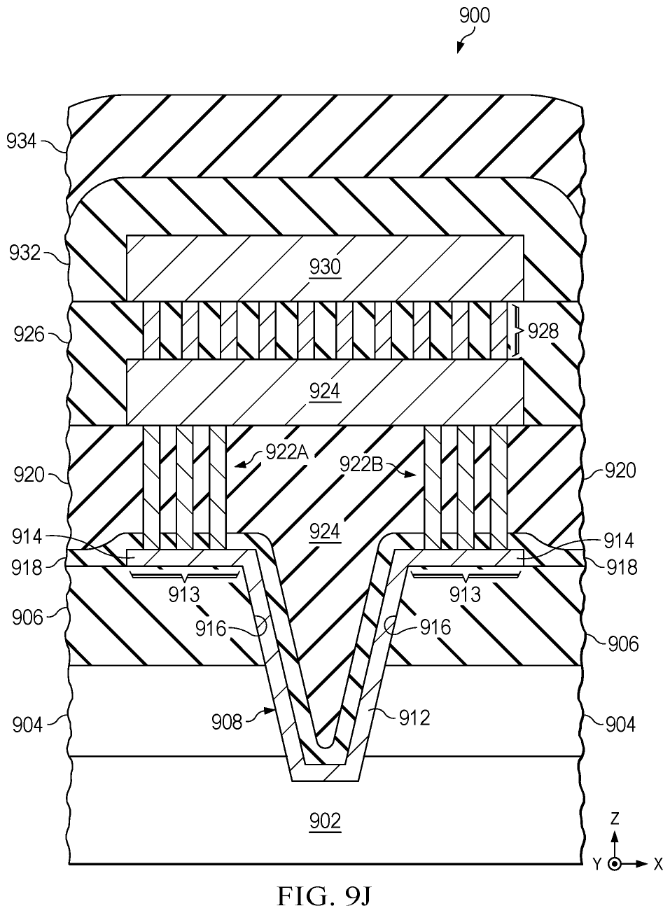

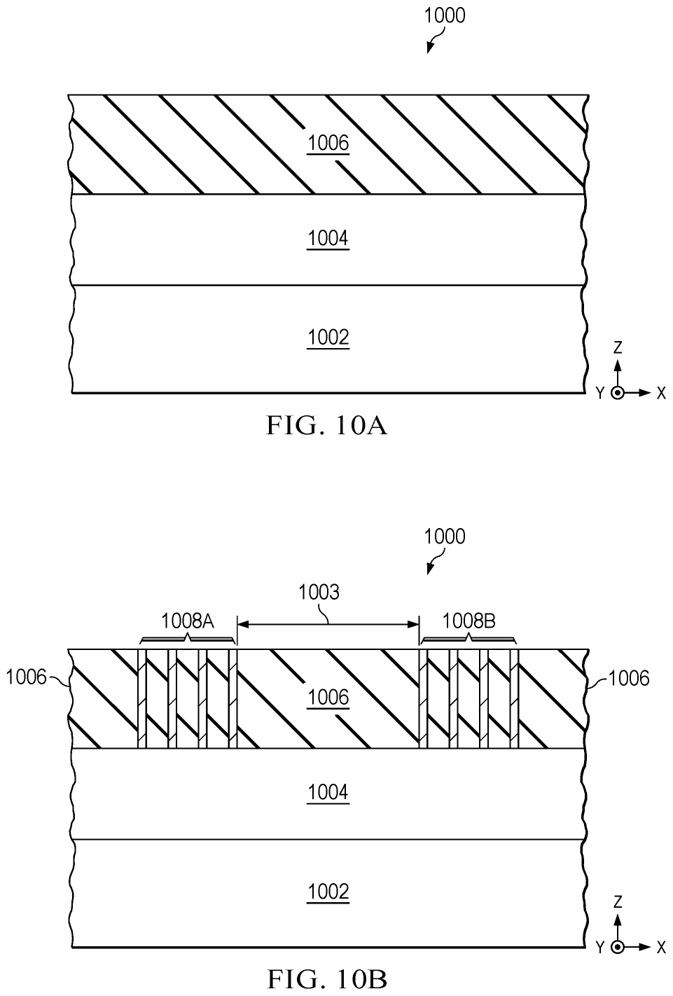

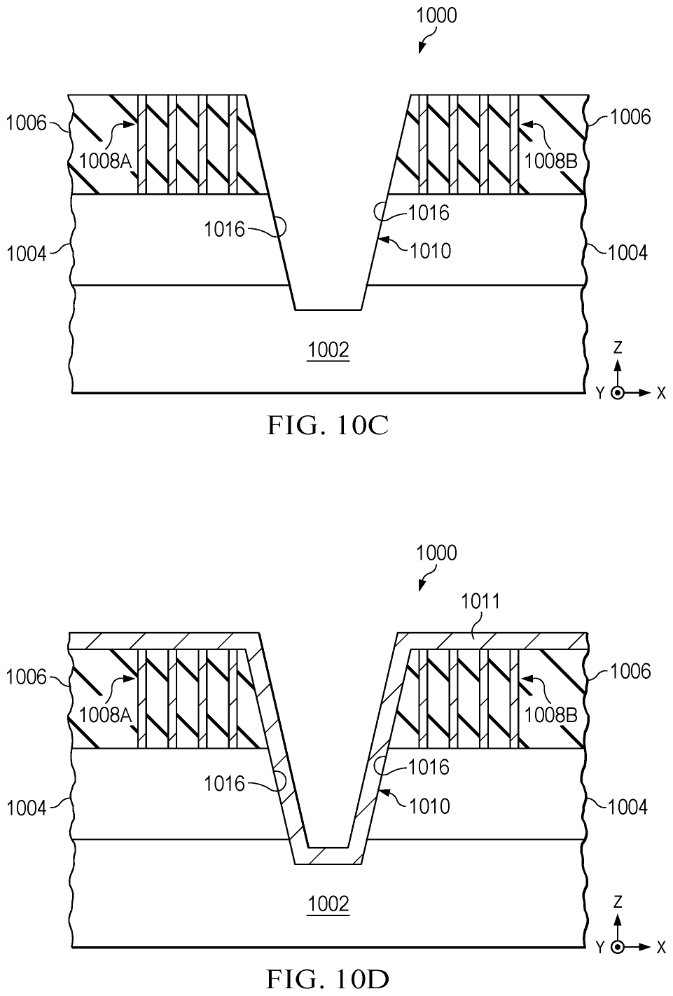

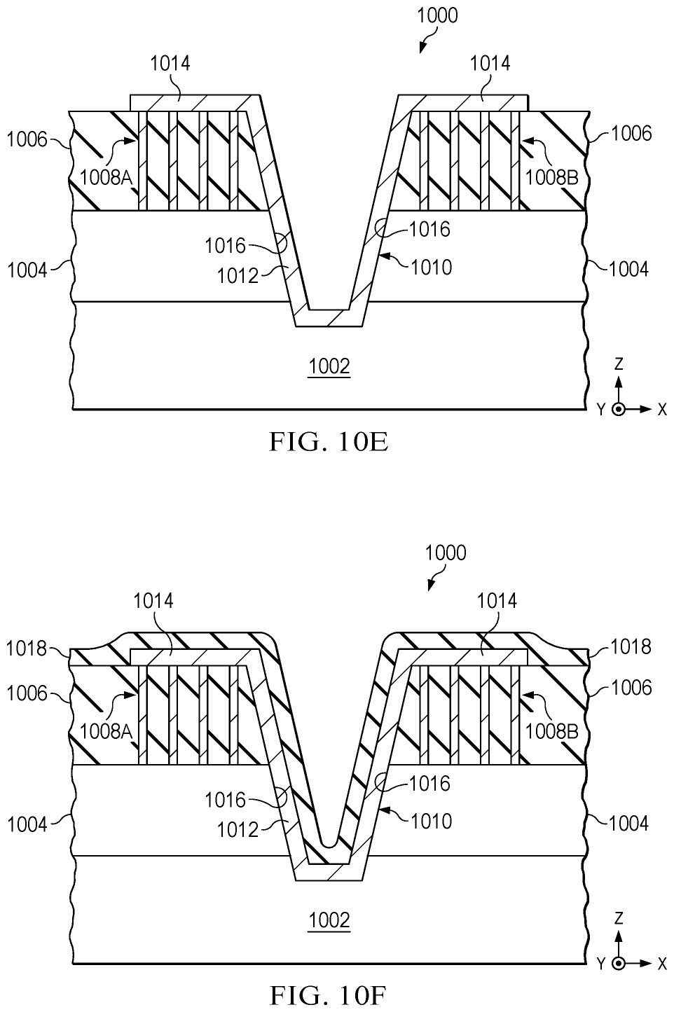

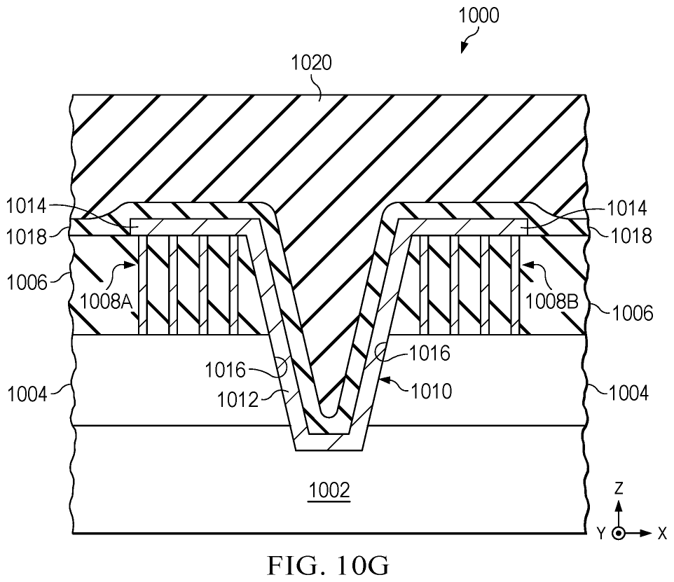

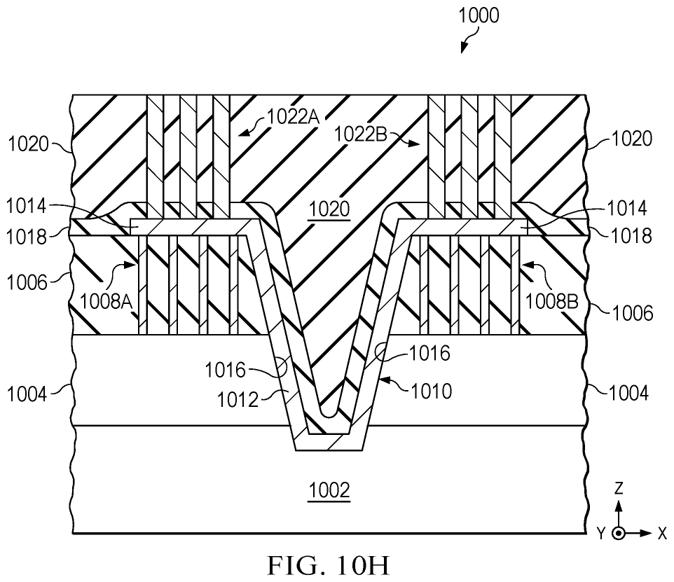

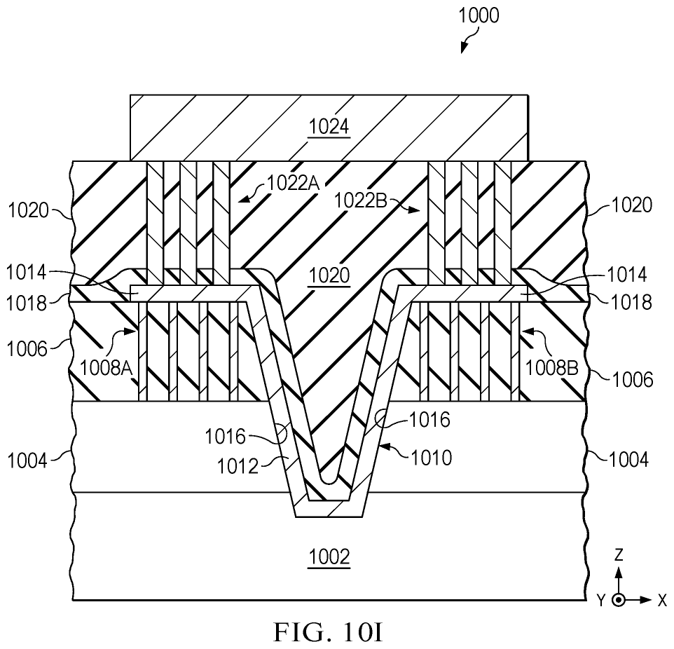

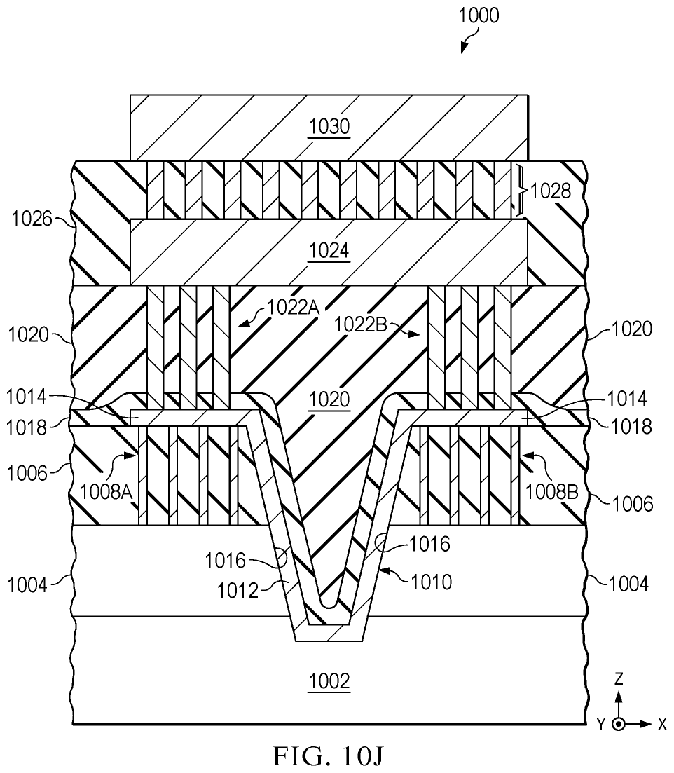

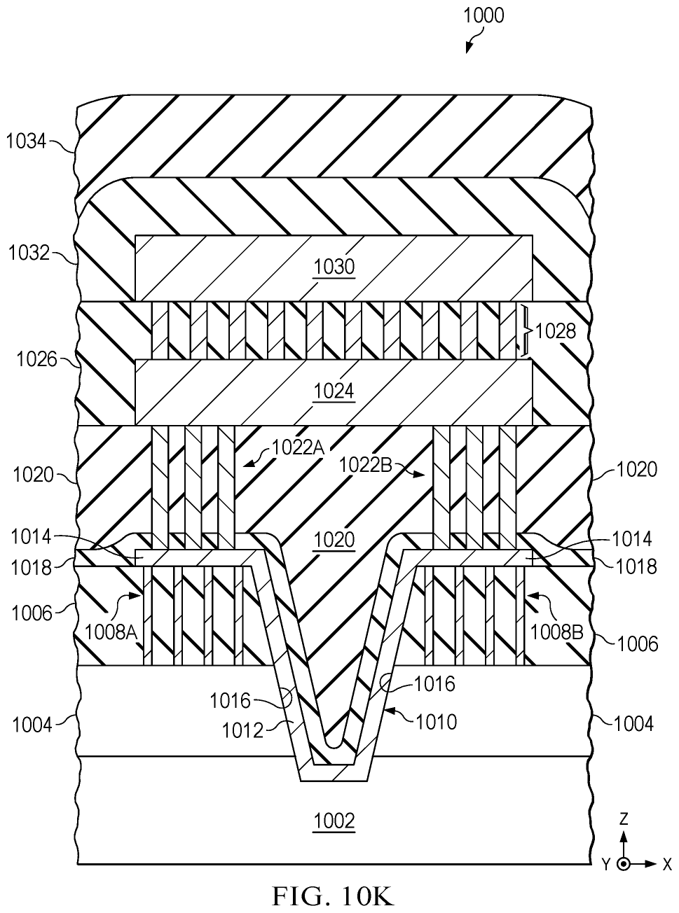

FIGS. 9A-9J depict cross-sectional views roughly corresponding to aspects of a combination of process steps of the methods 400 and 500 shown in FIGS. 4 and 5, respectively, where a GR structure including a discontinuity is formed after forming the III-N devices of a semiconductor device 900. Similarly, FIGS. 10A-10K depict cross-sectional views roughly corresponding to aspects of a combination of process steps of the methods 400 and 500 described above, including an optional variation of forming contacts through a first dielectric layer as part of the GR structure of a semiconductor device 1000. As set forth above in detail with respect to the methods 400 and 500, the GR discontinuity may comprise a trench having a metal liner formed of a first metal layer (e.g., as part of MET1 of metallization during the fabrication of an example semiconductor device).

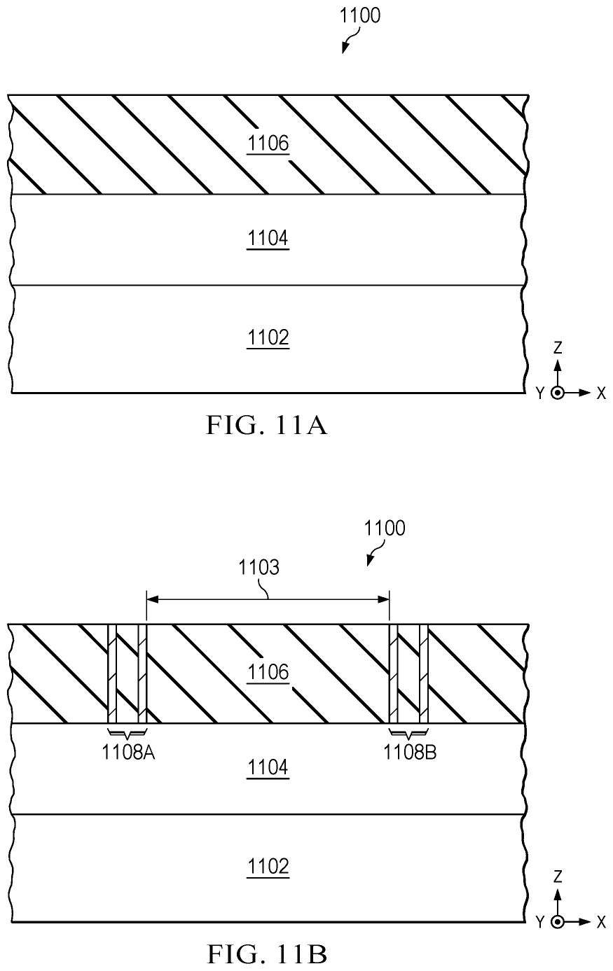

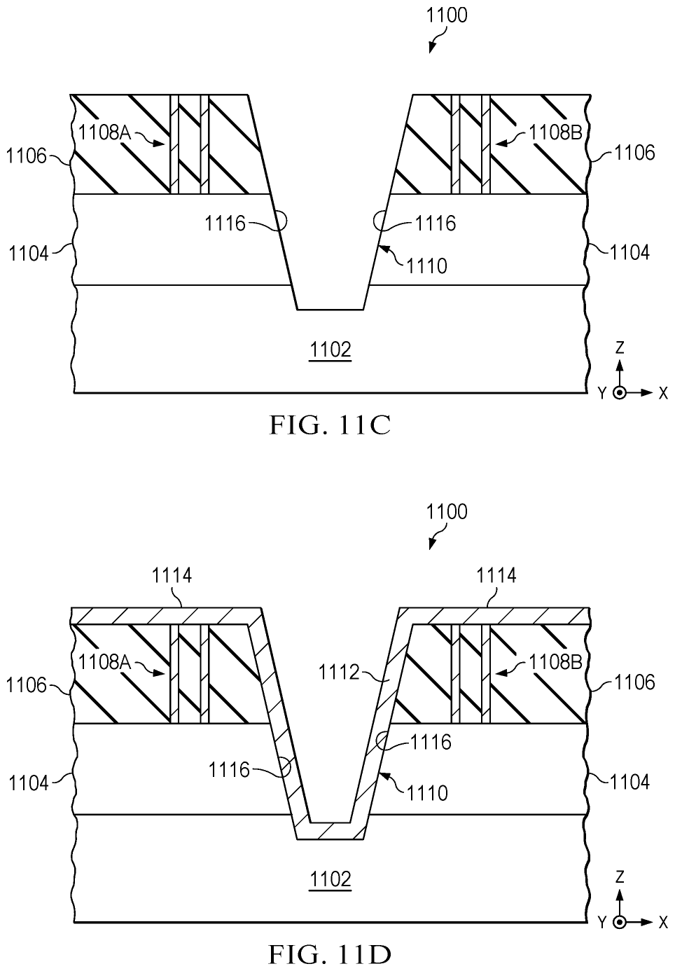

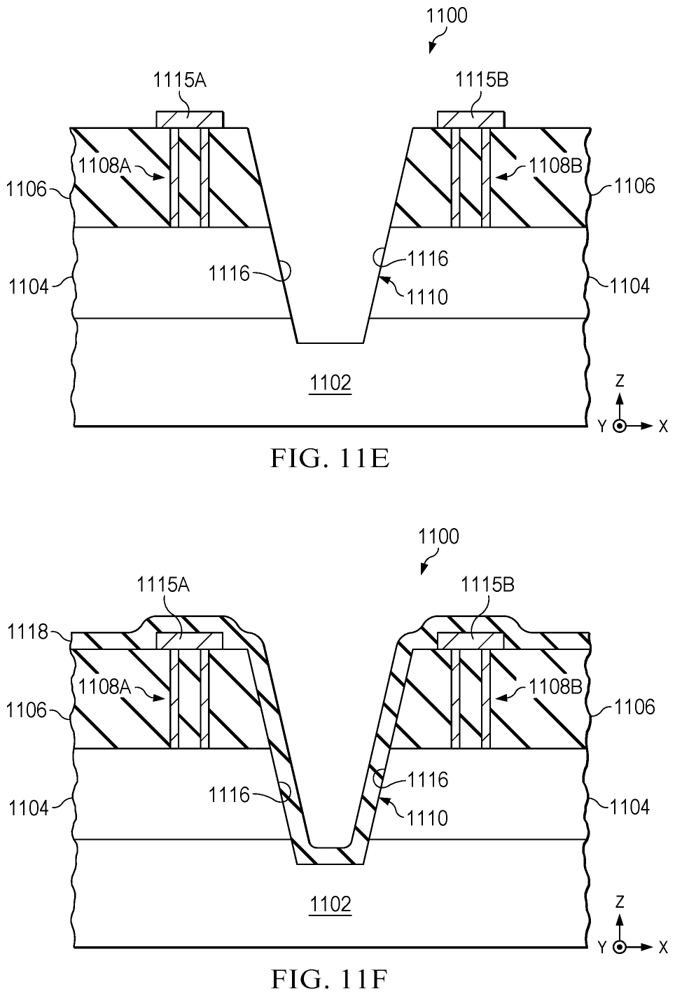

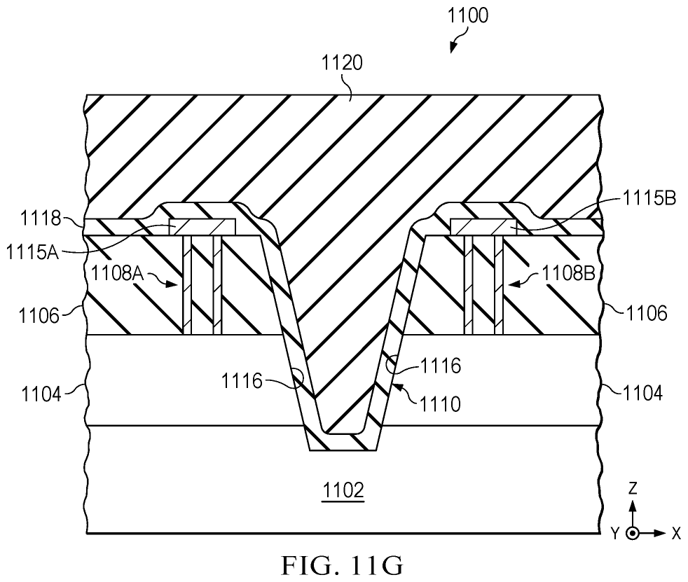

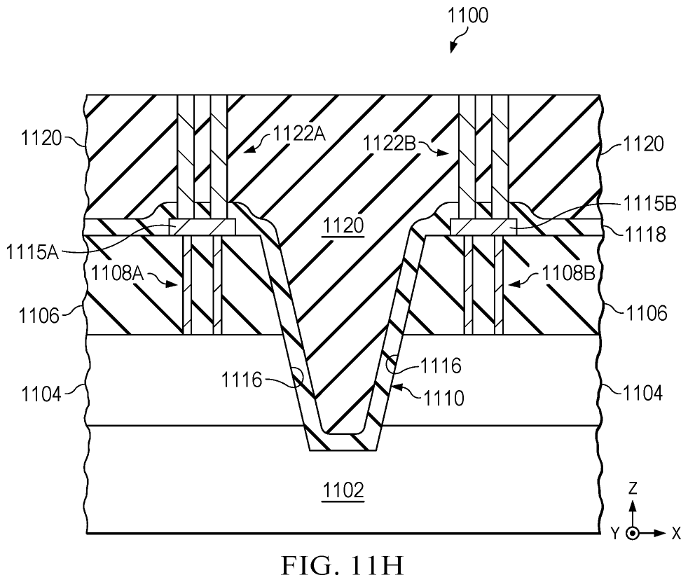

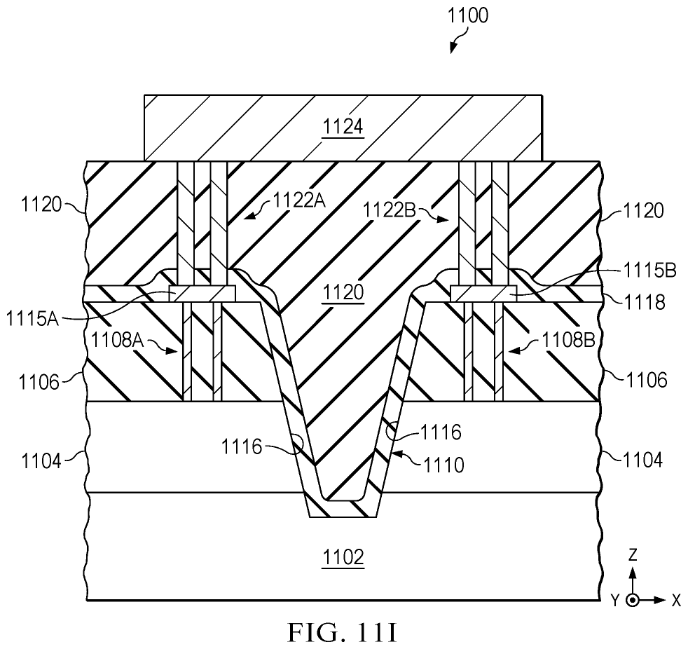

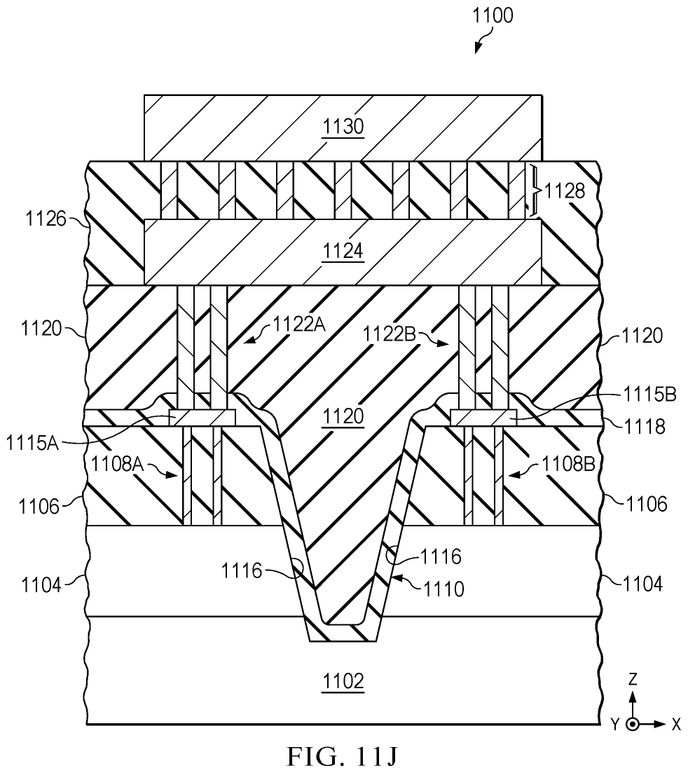

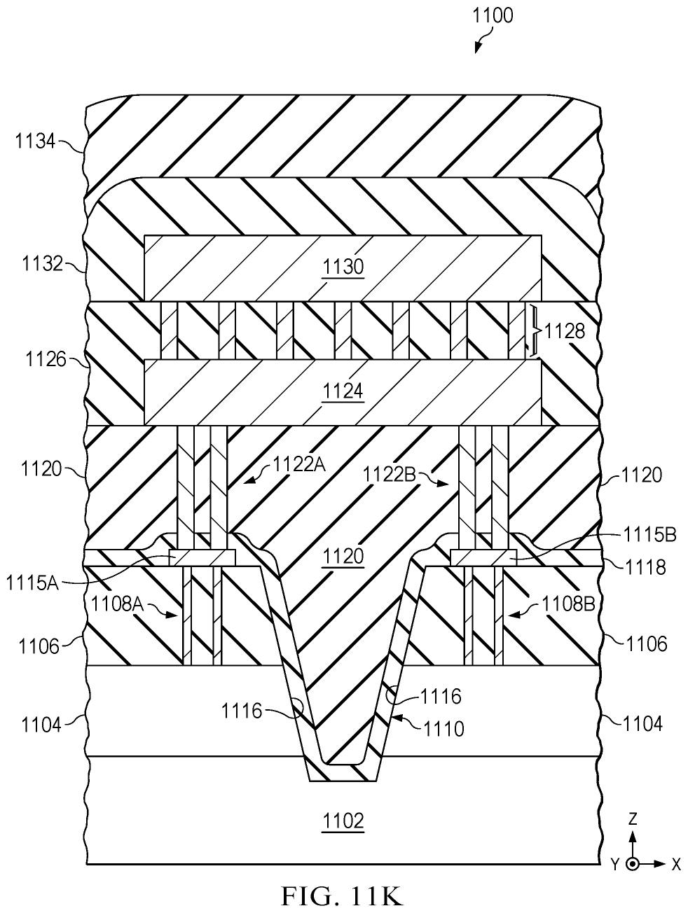

FIGS. 11A-11K depict cross-sectional views roughly corresponding to aspects of a combination of process steps of the methods 400 and 600 described above, where a GR discontinuity that is devoid of a metal liner in the trench is formed after forming the III-N devices of a semiconductor device 1100. Various process stages set forth in the foregoing cross-sectional views may be performed in a manner similar to the processes described above with respect to the cross-sectional views of FIGS. 8A-80. Accordingly, the description set forth above regarding FIGS. 8A-80 may also be applied to the cross-sectional views of FIGS. 9A-9J, FIGS. 10A-10K and FIGS. 11A-11K, in relevant parts and with suitable modifications.

Turning to FIG. 9A, a process stage is depicted where a first dielectric layer 906, e.g., comprising a PMD layer stack, is formed over a III-N layer 904 that is epitaxially formed over a semiconductor substrate 902 of the semiconductor device 900. As set forth previously, by this stage, suitable III-N devices will have been formed in a device region (not shown in FIGS. 9A-9J) of the semiconductor device 900, roughly corresponding to aspects of blocks 402-406 of the method 400. FIG. 9B depicts a process stage after forming a trench 908 of suitable dimensions through the first dielectric layer 906 and the III-N layer stack 904, and with interior surfaces 916 extending into the semiconductor substrate 902, corresponding to block 504 of the method 500 according to one implementation option.

FIG. 9C depicts a process stage where a first metal layer 910 is formed over the first dielectric layer 906, thus lining interior surfaces 916 of the trench 908. FIG. 9D depicts a process stage where the first metal layer 910 is patterned to form a metal liner 912 extending over and/or along the interior surfaces 916 of the trench 908. The metal liner 912 may also include a portion 914 extending over the first dielectric layer 906, e.g., on each side of the trench 908. In some examples, the metal liner 912 may have a thickness of about 100 nm to 500 nm. In some examples, the extension portion 914 may extend horizontally and/or laterally over the first dielectric layer 906 on each side of the trench 908 (e.g., along the X-axis and/or Y-axis, depending on orientation) having a configurable length 913, e.g., 3 μm to 5 μm, which may be of equal or unequal size on each side. The foregoing aspects of metal liner formation roughly correspond to aspects of blocks 506 and 508.

FIG. 9E depicts a process stage where a SiN layer 918 is optionally deposited over the first dielectric layer 906 and the portion 914. An ILD/IMD layer 920 comprising oxide is deposited over the SiN layer 918 as depicted in FIG. 9F. In some arrangements, the SiN layer 918 may be formed as an optional sublayer of a second dielectric layer including the ILD/IMD layer 920, roughly corresponding to aspects of block 510. The trench 908 having the metal liner 912 is filled with dielectric materials. FIG. 9G depicts a process stage after forming one or more conductive vias 922A and 922B of suitable dimensions through the second dielectric layer 920, including any sublayers 918, where the conductive vias 922A, 922B may be coupled to the respective portion 914 on each side of the trench 908, corresponding to aspects of block 512.

FIG. 9H depicts a process stage where a second metal layer is formed and patterned over the second dielectric layer 920 (e.g., as part of MET2 metallization) to form a metal plate 924, e.g., a first metal plate, coupled to the conductive vias 922A, 922B, corresponding to aspects of block 514. As before, whereas the metal plate 924 is depicted in the cross-sectional views as a planar member spanning over and coupled to the underlying conductive vias 922A, 922B, the metal plate 924 is representative of a planar annular metal structure surrounding a device region of the semiconductor device 900.

FIG. 9I depicts a process stage where a next level IMD/ILD layer 926 is deposited as a third dielectric layer over the metal plate 924, through which one or more conductive vias 928 are formed similar to the conductive vias 922/922B. Further, a third metal layer is formed and patterned over the third dielectric layer 926 (e.g., as part of MET3 metallization) to form a second metal plate 930 coupled to the conductive vias 928. As set forth at block 516, the foregoing stages of metal layer deposition/patterning, deposition of dielectric layers and inter-level via formation may be repeated sequentially, resulting in a metal stack of multiple metal plates depending on the number of metallization levels used for forming the GR structure in an example implementation. In FIG. 9J, a multi-layer PO structure, e.g., including a PO oxide layer 932 and a PO nitride layer 934 having respective thicknesses are formed over the resulting metal stack, e.g., including the metal plate 930 and associated dielectric layers 926, 920, to complete the fabrication of the semiconductor device 900.

The cross-sectional views shown in FIGS. 10A-10K include an optional variation in the foregoing flow, where the optional variation includes forming one or more contacts formed through a first dielectric layer before forming a trench, roughly corresponding to aspects of block 502 of the method 500. Except for this variation, the cross-sectional views of FIGS. 10A-10K depict process stages that are essentially similar to the process stages shown in FIGS. 9A-9J. Accordingly, only a summarized description of the cross-sectional views of FIGS. 10A-10K is set forth below.

In FIG. 10A, a process stage is depicted where a first dielectric layer 1006 is formed over a III-N layer 1004 that is epitaxially formed over a semiconductor substrate 1002 of a semiconductor device 1000. FIG. 10B depicts a process stage after forming one or more contacts 1008A and 1008B, e.g., arranged in two sets, each set including one or more rows or columns and separated apart by a lateral distance 1003, through the first dielectric layer 1006. In some arrangements, the contacts 1008A and 1008B may be formed in a manner similar to the process stage shown in FIG. 8G, illustrating the contacts 814A, 814B. Whereas the process stage of FIG. 8G already includes a trench that is filled with dielectric material, there is no trench formed yet in the process stage of FIG. 10B. The placement of the contact sets 1008A and 1008B may therefore be preconfigured relative to a trench to be formed at a subsequent process stage, where the lateral distance 1003 is sufficient to accommodate the trench. As shown in FIG. 10C, a trench 1010 having interior surfaces 1016 is formed between the contact rows 1008A and 1008B, roughly corresponding to the process stage shown in FIG. 9B.

FIG. 10D depicts a process stage where a first metal layer 1011 is formed over the first dielectric layer 1006 such that the first metal layer 1011 lines the interior surfaces 1016 of the trench 1010. FIG. 10E depicts a process stage where the first metal layer 1011 is patterned to form a metal liner 1012 extending over and/or along the interior surfaces 1016 of the trench 1010. As before, the metal liner 1012 also includes a portion 1014 extending over the first dielectric layer 1006 at least for a length overlapping the contacts 1008A and 1008B on each side of the trench 1010. FIG. 10F depicts a process stage where a SiN layer 1018 is optionally deposited over the first dielectric layer 1006 and the portion 1014. An ILD/IMD layer 1020 comprising oxide is deposited over the SiN layer 1018 as depicted in FIG. 10G. Similar to the arrangements set forth above, the SiN layer 1018 may be formed as an optional sublayer of a second dielectric layer including the ILD/IMD layer 1020 for filling the trench 1010.

FIG. 10H depicts a process stage after forming one or more conductive vias 1022A and 1022B of suitable dimensions through the second dielectric layer 1020, including any sublayers 1018, where the conductive vias 1022A, 1022B are coupled to the respective portion 1014 on each side of the trench 1010. FIG. 10I depicts a process stage where a second metal layer is formed and patterned over the second dielectric layer 1020 (e.g., as part of MET2 metallization) to form a metal plate 1024, e.g., a first metal plate, coupled to the conductive vias 1022A, 1022B, surrounding a device region of the semiconductor device 1000. FIG. 10J depicts a process stage where a next level IMD/ILD layer 1026 is deposited as a third dielectric layer over the metal plate 1024, through which one or more conductive vias 1028 are formed similar to the conductive vias 1022A/1022B.

Further, a third metal layer is formed and patterned over the third dielectric layer 1026 (e.g., as part of MET3 metallization) to form a second metal plate 1030 coupled to the conductive vias 1028. A multi-layer PO structure, e.g., including a PO oxide layer 1032 and a PO nitride layer 1034 having respective thicknesses are formed over the resulting metal stack, e.g., including the metal plate 1030 and associated dielectric layers 1026, 1020, to complete the fabrication of the semiconductor device 1000, as illustrated in FIG. 10K. As before, the foregoing stages of metal layer deposition/patterning, deposition of dielectric layers and inter-level via formation may be repeated sequentially prior to PO formation, thus resulting in a metal stack of multiple metal plates depending on the number of metallization levels used for forming the GR structure in an example implementation.

Turning to the cross-sectional views of FIGS. 11A-11K, a process stage is depicted in FIG. 11A where a first dielectric layer 1106, e.g., comprising a PMD layer stack, is formed over a III-N layer 1104 that is epitaxially formed over a semiconductor substrate 1102 of the semiconductor device 1100. Similar to the examples set forth previously, by this stage, suitable III-N devices will have been formed in a device region (not shown in FIGS. 11A-11K), roughly corresponding to certain aspects of blocks 402-406 of the method 400. FIG. 11B depicts a process stage after forming one or more contacts 1108A and 1108B through the first dielectric layer 1106, where the contacts 1108A and 1108B may be formed in a manner similar to the process stage shown in FIG. 8G, illustrating the contacts 814A, 814B. Similar to the process stage of FIG. 10B, there is no trench formed yet in the process stage of FIG. 11A. Accordingly, the placement of the contacts 1108A and 1108B may be preconfigured, e.g., arranged in two sets, each set including one or more contacts and separated by a lateral distance 1103 sufficient to accommodate to a trench 1110 to be formed between the rows of contacts 1108A and 1108B at a subsequent process stage, as shown in FIG. 11C, roughly corresponding to aspects of blocks 602 and 604 of the method 600.

Similar to the previous arrangements, FIG. 11C depicts a process stage after forming the trench 1110 of suitable dimensions through the first dielectric layer 1106 and the III-N layer stack 1104, and having interior surfaces 1116 extending into the semiconductor substrate 1102. FIG. 11D depicts a process stage where a first metal layer 1112 is formed over the first dielectric layer 1106 such that the first metal layer 1112 lines interior surfaces 1116 of the trench 1110 and horizontally extending over the contacts 1108A, 1108B as extension portions 1114, corresponding to aspects of block 606. FIG. 11E depicts a process stage where the first metal layer 1112 is patterned to form landing pads 1115A and 1115B over the corresponding sets of contacts 1108A, 1108B from the extension portions 1114 while removing the metal from the interior surfaces 1116 of the trench 1110, corresponding to aspects of block 608. FIG. 11F depicts a process stage where a SiN layer 1118 is optionally deposited over the first dielectric layer 1106 and the landing pads 1115A/1115B. An ILD/IMD layer 1120 comprising oxide is deposited over the SiN layer 1118 as depicted in FIG. 11G. Similar to the previous arrangements, the SiN layer 1118 may be formed as an optional sublayer of a second dielectric layer including the ILD/IMD layer 1120 for filling the trench 1110.

FIG. 11H depicts a process stage after forming one or more conductive vias 1122A and 1122B of suitable dimensions through the second dielectric layer 1120, including any sublayers 1118, where the conductive vias 1122A, 1122B may be coupled to the respective landing pads 1115A, 1115B on each side of the trench 1110. FIG. 11I depicts a process stage where a second metal layer is formed and patterned over the second dielectric layer 1120 (e.g., as part of MET2 metallization) to form a metal plate 1124, e.g., a first metal plate, coupled to the conductive vias 1122A, 1122B, surrounding a device region of the semiconductor device 1100. FIG. 11J depicts a process stage where a next level IMD/ILD layer 1126 is deposited as a third dielectric layer over the metal plate 1124, through which one or more conductive vias 1128 ae formed similar to the conductive vias 1122A/1122B.

Further, a third metal layer is formed and patterned over the third dielectric layer 1126 (e.g., as part of MET3 metallization) to form a second metal plate 1130 coupled to the conductive vias 1128. Similar to the previous arrangements, FIG. 11K depicts a process stage illustrating a multi-layer PO structure, e.g., including a PO oxide layer 1132 and a PO nitride layer 1034 having respective thicknesses formed over the resulting metal stack, e.g., including the metal plate 1130 and associated dielectric layers 1126, 1120, to complete the fabrication of the semiconductor device 1000. As before, the foregoing stages of metal layer deposition/patterning, deposition of dielectric layers and inter-level via formation may be repeated sequentially prior to PO formation in the process stage of FIG. 11K, thus resulting in a metal stack of multiple metal plates depending on the number of metallization levels used for forming the GR structure in an example implementation.

Whereas the foregoing examples set forth in FIGS. 10A-10K and FIGS. 11A-11K illustrate the formation of a GR trench after a PMD stage (e.g., before a first metal layer), additional and/or alternative examples of the present disclosure may include forming one or more GR trenches after the formation of various dielectric layers that may be deposited at successive stages in a multi-level interconnect system of a semiconductor device. For example, GR trenches may be formed after a first ILD layer (e.g., before a second metal layer, a second ILD layer (e.g., before a third metal layer), and so on, as previously noted.

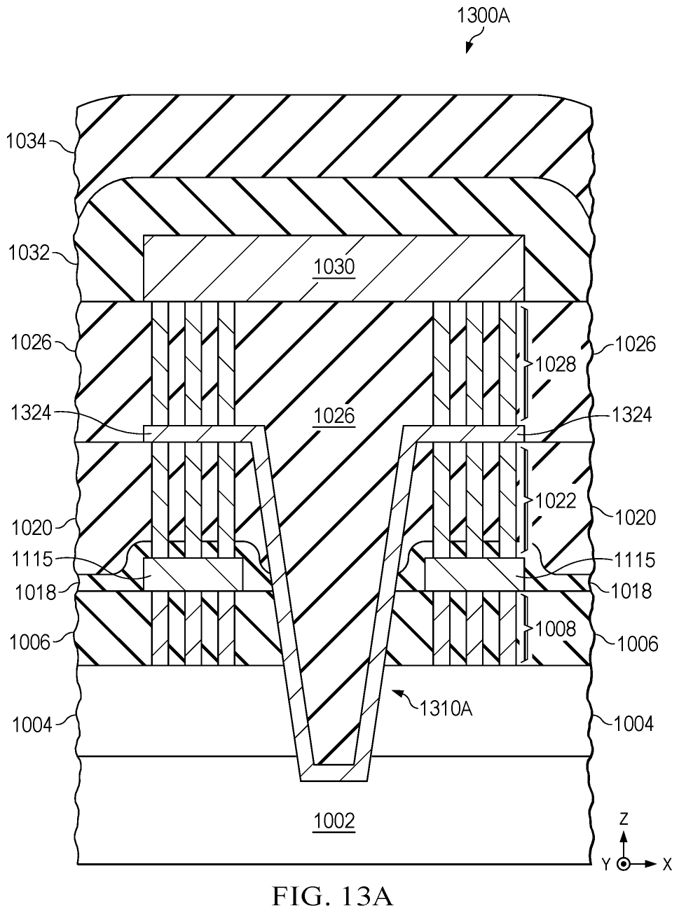

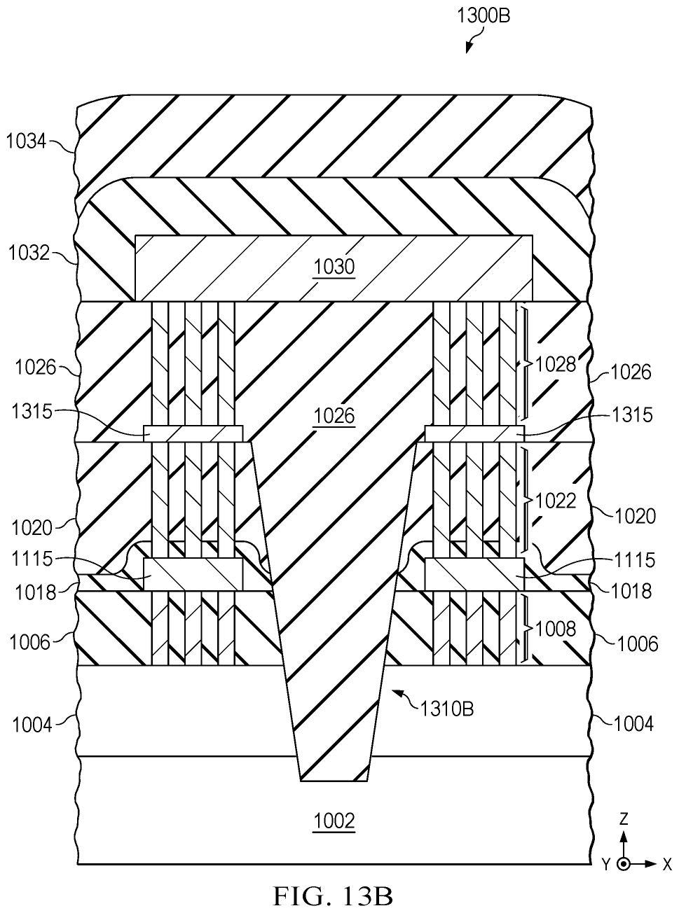

Turning to FIGS. 13A and 13B, reference numbers 1300A and 1300B respectively refer to the cross-sectional views of semiconductor devices where a GR trench is formed after a first ILD layer, e.g., ILD 1020, according to two representative arrangements. As illustrated in FIG. 13A, the semiconductor device 1300A includes a GR trench 1310A formed after forming the dielectric layer 1020. In some examples, the GR trench 1310A may be formed after patterning a first metal layer to form landing pads 1115 (similar to the formation of the landing pads 1115A/1115B set forth above) and forming the dielectric layer 1020 above the landing pads 1115. In some examples, the GR trench 1310A may be formed after forming sets of vias 1022 through the dielectric layer 1020 (similar to the formation of the vias 1022A and 1022B set forth above). Likewise, a SiN layer 1018 may be optionally formed over the landing pads 1115 as a sublayer of the dielectric layer 1020, which is partially removed as part of a trench etch for forming the trench 1310A prior to second level metallization.

After forming the trench 1310A (e.g., between the sets of vias 1022 and underlying sets of contacts 1008 formed in the PMD layer 1006 similar to the arrangements set forth previously), a metal liner 1324 is formed from a second metal layer, where the metal liner 1324 include a portion or an extension forming a collar or flange extending over a surface of the dielectric layer 1020 on either or both sides of the trench 1310A (similar to the formation of the metal liner 1014 described above). Thereafter, the trench 1310A is filled with material from a next level dielectric layer, e.g., the dielectric layer 1026. One or more sets of vias 1028 may be formed that land on respective horizontal extension portions of the metal liner 1324. A metal plate 1030 overlying the vias 1028 is patterned from a third metal layer, which may be covered by a multi-layer PO structure, e.g., including a PO oxide layer 1032 and a PO nitride layer 1034, as previously set forth.

In the example of FIG. 13B, a GR trench 1310B is also formed after the dielectric layer 1020 similar to the arrangement set forth in FIG. 13A. Instead of forming a metal liner along the entire interior surfaces of the trench 1310B, portions operable as landing pads 1315 are formed that overlie a surface of the dielectric layer 1020. Similar to the arrangement of FIG. 13A, trench filling, formation of vias, and metal plate patterning may be performed to obtain the GR stack structure of the semiconductor device 1300B.

In some examples, at least one of the contacts 1008, the landing pads 1115, and the vias 1022 may be omitted from the examples depicted in FIG. 13A and/or FIG. 13B. More specifically, the contacts 1008 or the vias 1022 may be omitted in an example. In another example, both the contacts 1008 and the vias 1022 may be omitted. In yet another example, the contacts 1008, the landing pads 1115, and the vias 1022 may be omitted.

In similar manner, GR trenches having greater vertical topographies (e.g., a height along the Z-axis) may be formed by staging the trench formation after the formation of each successive additional dielectric layer of an interconnect system, where a trench may be provided with a full or partial metal liner or without, in accordance with additional and/or alternative examples of the present disclosure.

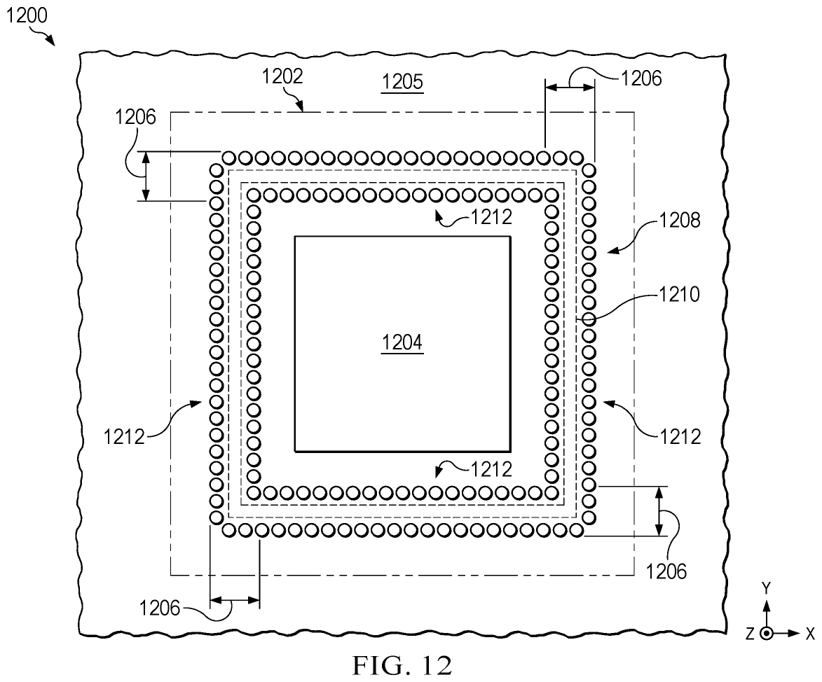

FIG. 12 depicts a top plan view of a wafer portion 1200 including a semiconductor device 1202 (or an IC die) with a GR structure according to some examples of the present disclosure, where the semiconductor device 1202 may be a representative example of the semiconductor devices 102 and 201 described above. As illustrated, the semiconductor device 1202 includes a device region 1204, roughly analogous to the device regions 110 and 202 set forth previously, which may be continuously surrounded by a GR region 1212 that includes a single GR 1206. A scribe lane region 1205, roughly analogous to the scribe lane region 206 and suitably dimensioned to support a cutting path, is disposed on and/or adjacent to each side of the semiconductor device 1202. GR 1206 includes a discontinuity 1210 comprising a trench feature according to any of the examples set forth above. Moreover, GR 1206 includes one or more rows of contacts and/or vias, collectively referred to by reference number 1208, are provided on each side of the discontinuity 1210.

Depending on implementation, the number of contacts and/or vias 1208 may vary and may be formed in various shapes and sizes. In some examples, contacts and/or vias 1208 may be provided as discrete structures—e.g., individual contacts and/or vias having a cylindrical shape. In some examples, contacts and/or vias 1208 may be provided as continuous structures—e.g., contacts and/or vias having a wall shape at least partially surrounding the device region 1204. In some examples, the contacts and/or vias 1208 may include combinations of discrete and continuous structures. In one example arrangement, GR 1206 is roughly analogous to a single GR, e.g., GR 205A, shown in the GR structure 203 of FIG. 2, and may include one or more rectangular metal frames or plates (not shown in FIG. 12), that is configured to arrest the propagation of any cracks emanating from the scribe lane region 1205 and directed towards the semiconductor device 1202 during singulation.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A semiconductor device, comprising:
a semiconductor substrate;
a III-N layer over the semiconductor substrate, the III-N layer extending past a device region of the semiconductor substrate; and
a guard ring surrounding the device region, the guard ring including a discontinuity formed through the III-N layer and extending into the semiconductor substrate.

2. The semiconductor device as recited in claim 1, wherein the discontinuity comprises a trench having a metal liner and filled with one or more dielectric materials, the metal liner formed of a first metal layer.

3. The semiconductor device as recited in claim 2, wherein the metal liner includes a portion extending over a surface of a first dielectric layer disposed over the III-N layer.

4. The semiconductor device as recited in claim 3, wherein the guard ring includes a metal plate over the trench, the metal plate formed of a second metal layer and coupled to the portion with one or more conductive vias through a second dielectric layer between the first and second metal layers.

5. The semiconductor device as recited in claim 3, wherein the guard ring includes one or more contact posts through the first dielectric layer and underlying the portion.

6. The semiconductor device as recited in claim 1, wherein the discontinuity comprises a trench filled with one or more dielectric materials.

7. The semiconductor device as recited in claim 6, wherein the guard ring comprises:
one or more pads formed of a first metal layer over a surface of a first dielectric layer disposed over the III-N layer, the one or more pads proximate to an upper rim of the trench; and
one or more contact posts through the first dielectric layer and underlying the pads.

8. The semiconductor device as recited in claim 7, wherein the guard ring further comprises a metal plate over the trench, the metal plate formed of a second metal layer and coupled to the one or more pads with one or more conductive vias through a second dielectric layer between the first and second metal layers.

9. A method, comprising:
forming a III-N layer over a semiconductor substrate that includes a device region, a guard ring region, and a scribe lane region; and
forming a guard ring in the guard ring region, wherein the guard ring surrounds the device region and includes a discontinuity formed through the III-N layer, the discontinuity extending into the semiconductor substrate.

10. The method as recited in claim 9, wherein the discontinuity is formed before forming a transistor in the device region.

11. The method as recited in claim 10, further comprising:
depositing a first dielectric material over the III-N layer;
forming a trench in the III-N layer through the first dielectric material and extending into the semiconductor substrate;
depositing a second dielectric material over the first dielectric material, wherein the trench is filled with the second dielectric material as a result of depositing the second dielectric material;
removing the second dielectric material outside the trench to form a surface;
after forming the transistor in the device region, forming a first dielectric layer over the surface;
forming one or more contact posts through the first dielectric layer;
depositing a first metal layer over the first dielectric layer;
patterning the first metal layer to form one or more pads;
depositing a second dielectric layer over the first dielectric layer;
forming one or more conductive vias through the second dielectric layer, the one or more conductive vias coupled to the one or more pads;
depositing a second metal layer over the second dielectric layer; and
patterning the second metal layer to form a metal plate coupled to the one or more conductive vias.

12. The method as recited in claim 11, wherein the steps of depositing metal layers, depositing dielectric layers, and forming conductive vias are successively repeated to form a stack of additional metal plates over the trench.

13. The method as recited in claim 9, wherein the discontinuity is formed after forming a transistor in the device region.

14. The method as recited in claim 13, further comprising:
after forming the transistor, forming a first dielectric layer over the III-N layer;
forming one or more contact posts through the first dielectric layer;
forming a trench through the first dielectric layer and the III-N layer, the trench extending into the semiconductor substrate;
depositing a first metal layer over the first dielectric layer and over interior surfaces of the trench;
patterning the first metal layer to form one or more pads over the first dielectric layer while removing the first metal layer from the interior surfaces of the trench;
depositing a second dielectric layer over the first dielectric layer, wherein the trench is filled with the second dielectric layer;
forming one or more conductive vias through the second dielectric layer, the one or more conductive vias coupled to the one or more pads;
depositing a second metal layer over the second dielectric layer; and
patterning the second metal layer to form a metal plate coupled to the one or more conductive vias.

15. The method as recited in claim 14, wherein the steps of depositing metal layers, depositing dielectric layers, and forming conductive vias are successively repeated to form a stack of additional metal plates over the trench.

16. The method as recited in claim 13, further comprising:
after forming the transistor, forming a first dielectric layer over the III-N layer;
forming a trench through the first dielectric layer and the III-N layer, the trench extending into the semiconductor substrate;
depositing a first metal layer over the first dielectric layer and over interior surfaces of the trench;
patterning the first metal layer to form a metal liner along the interior surfaces of the trench, the metal liner including a portion over a surface of the first dielectric layer disposed over the III-N layer;
depositing a second dielectric layer over the first dielectric layer, wherein the trench is filled with the second dielectric layer;
forming one or more conductive vias through the second dielectric layer, the one or more conductive vias coupled to the portion;
depositing a second metal layer over the second dielectric layer; and
patterning the second metal layer to form a metal plate coupled to the one or more conductive vias.

17. The method as recited in claim 16, further comprising:
forming, prior to forming the trench, one or more contact posts through the first dielectric layer, the one or more contact posts for coupling to the portion over the surface of the first dielectric layer.

18. The method as recited in claim 16, wherein the steps of depositing metal layers, depositing dielectric layers, and forming conductive vias are successively repeated to form a stack of additional metal plates over the trench.

19. A semiconductor structure, comprising:
a semiconductor substrate;
a III-N layer over the semiconductor substrate, the III-N layer extending into a device region of the semiconductor substrate and into a scribe lane region of the semiconductor substrate; and
a discontinuity surrounding the device region, the discontinuity formed through the III-N layer and extending into the semiconductor substrate.

20. The semiconductor structure as recited in claim 19, wherein the discontinuity comprises a trench having a metal liner and filled with one or more dielectric materials, the metal liner formed of a first metal layer.

21. The semiconductor structure as recited in claim 20, wherein the metal liner includes a portion extending over a surface of a first dielectric layer disposed over the III-N layer.

22. The semiconductor structure as recited in claim 21, further comprising a metal plate over the trench, the metal plate formed of a second metal layer and coupled to the portion with one or more conductive vias through a second dielectric layer between the first and second metal layers.

23. The semiconductor structure as recited in claim 21, further comprising one or more contact posts through the first dielectric layer underlying the portion.

24. The semiconductor structure as recited in claim 19, wherein the discontinuity comprises a trench filled with one or more dielectric materials.

25. The semiconductor structure as recited in claim 24, further comprising:
one or more pads formed of a first metal layer over a surface of a first dielectric layer disposed over the III-N layer, the one or more pads proximate to an upper rim of the trench; and
one or more contact posts through the first dielectric layer underlying the one or more pads.

26. The semiconductor structure as recited in claim 25, further comprising a metal plate over the trench, the metal plate formed of a second metal layer and coupled to the one or more pads with one or more conductive vias through a second dielectric layer between the first and second metal layers.
